(19) United States
(12) Patent Application Publication
(10) Pub. No.: US 2026/0318996 A1
(43) Pub. Date: Oct. 15, 2026

(54) Storage Battery Deterioration Diagnosis Device, System, Method, and Program

(71) Applicant: Asahi Kasei Kabushiki Kaisha, Tokyo (JP)

(72) Inventors: Yuima Kimura, Tokyo (JP); Koichi Hiraoka, Tokyo (JP); Hitoshi Morita, Tokyo (JP); Masao Awatsu, Tokyo (JP)

(73) Assignee: Asahi Kasei Kabushiki Kaisha, Tokyo (JP)

(21) Appl. No.: 19/481,299

(22) PCT Filed: May 7, 2024
(86) PCT No.: PCT/JP2024/016945

§ 371 Date: Nov. 4, 2025

(30) Foreign Application Priority Data
May 8, 2023 (JP) 2023-076593
Oct. 30, 2023 (JP) 2023-185243

(51) Int. Cl. G01R 31/367; G01R 31/378; G01R 31/3842; G01R 31/389; G01R 31/392; H01M 10/42

(52) U.S. Cl. CPC G01R 31/367; G01R 31/378; G01R 31/3842; G01R 31/389; G01R 31/392; H01M 10/4285

(57) ABSTRACT

The purpose of the present disclosure is to provide a storage battery deterioration diagnosis device, a system, a method, and a program that can more accurately diagnose deterioration of the storage battery. A diagnosis device according to the present disclosure is used in an energy storage system. The diagnosis device comprises: a storage unit that stores a trained model trained to output material deterioration information about a storage battery when charge/discharge data is input; an acquisition unit that acquires charge/discharge data about the storage battery; a diagnosis unit that diagnoses the material deterioration information about the storage battery obtained by inputting the charge/discharge data about the storage battery to the trained model; and an output unit that outputs, as a diagnosis result, the material deterioration information obtained from the diagnosis unit.

### TECHNICAL FIELD

The present disclosure relates to a storage battery deterioration diagnosis device, system, method, and program.

### BACKGROUND ART

In recent years, from the viewpoint of preserving the global environment or effectively utilizing energy to save resources, attention has been drawn to power smoothing systems or late-night power storage systems for wind power generation, power storage systems used in combination with solar power generation, power storage systems for electric vehicles, etc. It is necessary that the batteries used in these power storage systems have high energy density. As a promising candidate of a high-energy density battery which can meet such requirements, the development of storage batteries exemplified by lithium-ion secondary batteries (hereinafter referred to as LiBs) has been actively pursued.

LiBs are generally constituted by a positive electrode including a positive electrode active material layer containing a positive electrode active material, a negative electrode including a negative electrode active material layer containing a negative electrode active material, a separator arranged between the positive electrode and the negative electrode, and an electrolyte. LiBs are created by assembling a cell and then doping the negative electrode active material with lithium ions by means of a charging process.

Due to their high energy density, LiBs have recently been used in electric vehicles and energy storage systems (ESSs). ESSs are often used to adjust the power output of renewable energy sources, the power generation of which is influenced by weather. Without power adjustment by ESSs, fluctuations in voltage and frequency can cause equipment malfunction, leading to instability, breakdowns, or even power generation equipment shutting down, resulting in power outages. Thus, it is important for ESSs to maintain a certain level of capacity and output and maintain a state in which they can always adjust to fluctuations in renewable energy, and accordingly, it is necessary to periodically diagnose the deterioration state of the storage batteries (deterioration diagnosis) and, if necessary, perform maintenance operations such as replacing the storage batteries.

As a technical approach to this problem, the technology of battery management systems (hereinafter referred to as BMSs) which detect and evaluate the state of charge (SoC), state of health (SoH), and state of safety (SoS) of storage batteries and which can control or stop the charging and discharging of an energy storage system before an accident occurs, as well as balance the cells when the SoCs thereof differ, has been developed. For example, the SoH can be evaluated by integrating the discharged power (W) of the energy storage system over time (hr) from 100% to 0% SoC to obtain the discharged energy E (Wh), and dividing this by the initial discharged energy E₀ (SoH=E/E₀×100(%)). By monitoring the SoH of the energy storage system, the operator of the energy storage system can optimize operation plans and take appropriate measures such as replacing storage batteries. Furthermore, regarding SoS, for example, voltage and temperature can be detected. For example, when LiBs are maintained at a high voltage of 4.5 V or higher, there is a risk of gas swelling or ignition due to decomposition of the electrolyte solvent and structural destruction of the positive electrode active material. To prevent this, BMSs comprise a mechanism for determining in advance an upper voltage limit at which LiBs can be used and stopping charging when the upper voltage limit is reached.

However, the method described above merely quantifies electrochemical data on the safety and reliability of a storage battery into management indicators such as SoH and SoS, and does not provide information on the deterioration of the storage battery material (hereinafter referred to as “material deterioration information”). Thus, a storage battery to be diagnosed can often be erroneously determined to be unusable based on indicators such as SoH and SoS, even if the storage battery is actually in a usable condition.

Several studies have been conducted on methods for diagnosing the deterioration of storage batteries in such energy storage systems. For example, Patent Literature 1 describes a method in which a predetermined voltage is applied to an energy storage system, the current response is detected, and the lithium (Li) deposition amount inside the battery is estimated based on the detected current. However, this method merely estimates the Li deposition amount from electrochemical data, and the actual state of Li generated in the energy storage system cannot be ascertained, whereby accurate deterioration diagnosis of the storage battery is impossible.

Patent Literature 2 describes a method for detecting internal short circuits from the electrochemical behavior of an internal short circuit itself. While this method directly evaluates the phenomenon of internal short circuits, highly accurate deterioration diagnosis of a storage battery cannot be performed due to the type of LiB and the influence of noise during measurement.

Patent Literature 3 describes a technology for determining whether lithium deposition has occurred by detecting the presence or absence of a local minimum point where a charging current changes from a decrease to an increase during constant voltage charging. However, because this method indirectly evaluates lithium deposition, accurate deterioration diagnosis of a storage battery is impossible.

Patent Literature 4 describes a technology for creating a database of correlations between overvoltage at the input and output of a storage battery and SoH, wherein this database is used as training data to construct a machine learning model to estimate SoH in real time from charge/discharge data during actual ESS operation. While this method is excellent for estimating the deterioration state of a storage battery in real time, the mode of such deterioration state cannot be understood. Thus, accurate deterioration diagnosis of a storage battery is impossible.

### CITATION LIST

### Patent Literature

[PTL 1] Japanese Unexamined Patent Publication (Kokai) No. 2010-86901
[PTL 2] Japanese Unexamined Patent Publication (Kokai) No. 2009-32506
[PTL 3] Japanese Unexamined Patent Publication (Kokai) No. 2012-3863
[PTL 4] WO 2017/022037

### Non-Patent Literature

[NPL 1] Zachary M. Konz, et al., “Detecting the Onset of Lithium Plating and Monitoring Fast Charging Performance with Voltage Relaxation,” American Chemical Society Energy Letter, (2020), 5(6), pp. 1750-1757

### SUMMARY OF INVENTION

### Technical Problem

As described above, conventional SoS- and SoH-based diagnoses merely estimate the state of a storage battery from electrochemical data, and often suffer from the problem of misdiagnosis. As a result, a storage battery may be erroneously diagnosed as having reached the end of its lifespan even when it is actually usable, or may be erroneously diagnosed as still usable even when immediate replacement thereof is actually necessary. Furthermore, if the diagnosis reveals a storage battery that has deteriorated to the point where immediate replacement is necessary, since continued operation thereof could lead to operational malfunction or ignition caused by ignition of the storage battery, the ESS must be temporarily stopped and maintenance (such as battery replacement) must be performed. However, from the point of view of the operator of the ESS, this results in a significant loss of opportunity, as the ESS must be stopped at an unplanned time.

Thus, one object of the present disclosure is to provide a storage battery deterioration diagnosis device, system, method, and program which enable more accurate storage battery deterioration diagnosis.

### Solution to Problem

Examples of embodiments of the present disclosure are listed in Items [1] to [45] below.

[1]

A diagnosis device for a storage battery used in an energy storage system, the diagnosis device comprising:
a storage part for storing a trained model A which is trained so as to output material deterioration information of a storage battery when charge/discharge data is input,
an acquisition part for acquiring charge/discharge data of the storage battery,
a diagnosis part for diagnosing material deterioration information of the storage battery obtained by inputting charge/discharge data of the storage battery into the trained model A, and
an output part for outputting the material deterioration information obtained from the diagnosis part as diagnosis results.
   [2]

The diagnosis device according to Item 1, wherein material information of the storage battery is material information of at least one selected from the group consisting of a positive electrode, a negative electrode, a separator, and an electrolyte of the storage battery.

[3]

The diagnosis device according to Item 2, further comprising a calculation part for calculating a lithium deposition risk X of the storage battery based on information including the material deterioration information, wherein the diagnosis results include the lithium deposition risk X.

[4]

The diagnosis device according to Item 3, wherein the calculation part calculates a lithium deposition risk X of the storage battery based on the material deterioration information and information including at least one selected from the group consisting of the charge/discharge data, material information of the storage battery, and an operation condition of the energy storage system.

[5]

The diagnosis device according to Item 4, wherein the calculation part calculates a lithium deposition risk X of the storage battery by calculating a sum of a value obtained by multiplying a lithium deposition risk X_{chem.} estimated from the material deterioration information by a weighting coefficient α_{chem.}, which depends on material information of a negative electrode of the storage battery, and a value obtained by multiplying a lithium deposition risk X_{elec.} estimated from the charge/discharge data by a weighting coefficient α_{elec.}, which depends on material information of a negative electrode of the storage battery, and optionally, multiplying the sum by at least one selected from the group consisting of a weighting coefficient β, which depends on material information of a positive electrode of the storage battery, and a weighting coefficient γ, which depends on the operation condition.

[6]

The diagnosis device according to any one of Items 1 to 5, wherein the diagnosis device further comprises a calculation part for calculating a deterioration state of the storage battery based on a state of health (SoH) of the storage battery estimated based on charge/discharge data of the storage battery, and the material deterioration information, and the output part outputs the deterioration state as diagnosis results.

[7]

The diagnosis device according to Item 6, wherein the calculation part is configured so as to calculate a lithium deposition risk X of the storage battery based on information including the material deterioration information, and label a deterioration state of the storage battery based on one or a plurality of predetermined thresholds for each of the SoH and the lithium deposition risk X, and the diagnosis results include results of the labeling.

[8]

The diagnosis device according to Item 7, wherein the output part transmits the diagnosis results to a terminal device of a user.

[9]

The diagnosis device according to Item 7, wherein the calculation part calculates an SoH and a lithium deposition risk Xt₁ at a current time point (t₁) based on the material deterioration information, charge/discharge data at a current time point (t₁), and optionally, information including at least one selected from the group consisting of material information of the storage battery and an operation condition of the energy storage system.

[10]

The diagnosis device according to Item 9, wherein material information of the storage battery is material information of at least one selected from the group consisting of a positive electrode, a negative electrode, a separator, and an electrolyte of the storage battery.

[11]

The diagnosis device according to Item 10, wherein the calculation part calculates a lithium deposition risk Xt₁ at the current time point (t₁) by calculating a sum of a value obtained by multiplying a lithium deposition risk X_{chem.} estimated from the material deterioration information by a weighting coefficient α_{chem.}, which depends on material information of a negative electrode of the storage battery, and a value obtained by multiplying a lithium deposition risk X_{elec.} estimated from the charge/discharge data by a weighting coefficient α_{elec.}, which depends on material information of a negative electrode of the storage battery, and optionally, multiplying the sum by at least one selected from the group consisting of a weighting coefficient β, which depends on material information of a positive electrode of the storage battery, and a weighting coefficient γ, which depends on the operation condition.

[12]

The diagnosis device according to Item 11, wherein the storage part further stores a trained model B which is trained so as to output a future lithium deposition risk X trend when information including an SoH and a lithium deposition risk Xt₁ at the current time point (t₁), past charge/discharge data, and a past SoH trend are input,
the diagnosis device further comprises a prediction part, and the prediction part inputs an SoH and a lithium deposition risk Xt₁ at the current time point (t₁) and information including past charge/discharge data and a past SoH trend into the trained model B to predict a future lithium deposition risk X trend, and
the calculation part calculates a lithium deposition risk Xt₂ at a certain future time point (t₂) based on the predicted future lithium deposition risk X trend, and labels a deterioration state of the storage battery based on one or a plurality of predetermined thresholds for the lithium deposition risk Xt₂.
   [13]

The diagnosis device according to Item 7, further comprising a control part for controlling the storage battery based on results of the labeling.

[14]

The diagnosis device according to Item 13, wherein the control part controls the storage battery based on results of the labeling and a cause of storage battery deterioration.

[15]

The diagnosis device according to Item 13, wherein the control part controls the storage battery based on results of the labeling and a target operation period of the energy storage system.

[16]

The diagnosis device according to Item 13, wherein the storage battery is composed of a plurality of storage battery modules arranged in series and/or parallel, each of which includes a plurality of cells arranged in series and/or parallel, the diagnosis part and a calculation part diagnose and label a deterioration state of each storage battery module, and the control part controls charge/discharge conditions for each storage battery module.

[17]

The diagnosis device according to Item 6, wherein material deterioration information of the storage battery is at least one selected from the group consisting of an area, a shape of a deposition region, a deposition weight, a distribution state, and a color tone of deposited lithium metal analyzed from an image of a negative electrode surface of the storage battery, a shape of lithium metal observed by cross-sectional SEM observation of a negative electrode, a chemical shift value (eV) and/or area thereof obtained from an Li(s1) spectrum obtained by XPS analysis, a chemical shift value (ppm) and/or area thereof obtained from a ⁷Li-NMR spectrum, and a g-value or a chemical state expressed as a line width obtained from an ESR spectrum.

[18]

The diagnosis device according to Item 6, wherein the charge/discharge data to be input to the trained model A is at least one selected from the group consisting of a voltage change over time (dOCV/dt-t plot) when the storage battery is charged to an arbitrary SoC and then immediately rested, a voltage change over time (V-t plot) during pulse charging and/or discharging at a constant current, a current change over time (I-t plot) observed during constant voltage charging, charge capacity and discharge capacity at a constant current or constant power, measurement data obtained by an AC impedance method, and mathematically processed data thereof.

[19]

The diagnosis device according to Item 6, wherein estimation of the SoH is performed by estimation based on capacity when the storage battery is charged and discharged at a constant current and a constant voltage, estimation based on internal resistance obtained by an AC impedance method, estimation based on internal resistance obtained from a slope of current-voltage characteristics (IV characteristics), estimation based on internal resistance obtained from voltage transient response when current is changed in steps, estimation by fitting charging curve data using a regression equation or a model, estimation based on an equivalent circuit or physical model which behaves in the same manner as the charge/discharge data of the storage battery, or a combination thereof.

[20]

The diagnosis device according to Item 19, wherein estimation of the SoH is performed by estimation based on internal resistance obtained from a slope of current-voltage characteristics (IV characteristics).

[21]

A diagnosis device for a storage battery used in an energy storage system, the diagnosis device comprising:
an acquisition part for acquiring charge/discharge data of the storage battery,
a reception part for receiving a trained model A for outputting material deterioration information from charge/discharge data of the storage battery,
a diagnosis part for diagnosing material deterioration information of the storage battery obtained by inputting charge/discharge data of the storage battery into the received trained model A, and
an output part for outputting the material deterioration information obtained from the diagnosis part as diagnosis results.
   [22]

The diagnosis device according to Item 21, wherein the diagnosis device further comprises a calculation part for estimating a state of health (SoH) of the storage battery based on charge/discharge data of the storage battery, and calculating a deterioration state of the storage battery based on the SoH and the material deterioration information, and the output part outputs the deterioration state as diagnosis results.

[23]

The diagnosis device according to Item 22, wherein the calculation part is configured so as to calculate a lithium deposition risk X of the storage battery based on information including the material deterioration information, and label a deterioration state of the storage battery based on one or a plurality of predetermined thresholds for each of the SoH and the lithium deposition risk X, and the diagnosis results include results of the labeling.

[24]

The diagnosis device according to Item 23, wherein the output part transmits the diagnosis results to a terminal device of a user.

[25]

The diagnosis device according to Item 23 or 24, further comprising a control part for controlling the storage battery based on results of the labeling.

[26]

A diagnosis system for a storage battery used in an energy storage system, the diagnosis system comprising:
a storage device for storing a trained model A which is trained so as to output material deterioration information of a storage battery when charge/discharge data is input,
an acquisition device for acquiring charge/discharge data of the storage battery,
a diagnosis device for diagnosing material deterioration information of the storage battery obtained by inputting charge/discharge data of the storage battery into the trained model A, and
an output device for outputting the material deterioration information obtained from the diagnosis device as diagnosis results.
   [27]

The diagnosis device according to Item 26, wherein the diagnosis system further comprises a calculation device for estimating a state of health (SoH) of the storage battery based on charge/discharge data of the storage battery, and calculating a deterioration state of the storage battery based on the SoH and the material deterioration information, and
the output device outputs the deterioration state as diagnosis results.
   [28]

The diagnosis system according to Item 27, wherein the calculation part is configured so as to calculate a lithium deposition risk X of the storage battery based on information including the material deterioration information, and label a deterioration state of the storage battery based on one or a plurality of predetermined thresholds for each of the SoH and the lithium deposition risk X, and the diagnosis results include results of the labeling.

[29]

The diagnosis system according to Item 28, wherein the diagnosis system further comprises a display device, and the output device transmits the diagnosis results to the display device and the display device displays the diagnosis results.

[30]

The diagnosis system according to Item 28 or 29, further comprising a controller for controlling the storage battery based on results of the labeling.

[31]

A diagnosis system for a storage battery used in an energy storage system, comprising a server and a diagnosis device, wherein
the server comprises:
a storage part for storing a trained model A which is trained so as to output material deterioration information of a storage battery when charge/discharge data is input, and
a transmission part for transmitting a trained model A stored in the storage part to a diagnosis device for diagnosing material deterioration information of the storage battery, and
the diagnosis device comprises:
an acquisition part for acquiring charge/discharge data of the storage battery,
a reception part for receiving the trained model A,
a diagnosis part for diagnosing material deterioration information of the storage battery obtained by inputting charge/discharge data of the storage battery into the received trained model A, and
an output part for outputting the material deterioration information obtained from the diagnosis part as diagnosis results.
   [32]

The diagnosis system according to Item 31, wherein the server further comprises:
a calculation part for estimating a state of health (SoH) of the storage battery based on charge/discharge data of the storage battery, and calculating a deterioration state of the storage battery based on the SoH and the material deterioration information, and
the output part outputs the deterioration state as diagnosis results.
   [33]

The diagnosis system according to Item 32, wherein the calculation part is configured so as to calculate a lithium deposition risk X of the storage battery based on information including the material deterioration information, and label a deterioration state of the storage battery based on one or a plurality of predetermined thresholds for each of the SoH and the lithium deposition risk X, and the diagnosis results include results of the labeling.

[34]

The diagnosis system according to Item 33, wherein the diagnosis system further comprises a display device, and the output part transmits the diagnosis results to the display device and the display device displays the diagnosis results.

[35]

The diagnosis system according to Item 33 or 34, further comprising a control part for controlling the storage battery based on results of the labeling.

[36]

A diagnosis method for a storage battery used in an energy storage system, the method comprising the steps of
acquiring charge/discharge data of the storage battery,
acquiring material deterioration information of the storage battery by inputting charge/discharge data of the storage battery into a trained model A which is trained so as to output material deterioration information of a storage battery when charge/discharge data is input,
diagnosing the obtained material deterioration information of the storage battery, and
outputting the material deterioration information as diagnosis results.
   [37]

The diagnosis method according to Item 36, characterized by the method further comprising the steps of estimating a state of health (SoH) of the storage battery based on charge/discharge data of the storage battery,
calculating a deterioration state of the storage battery based on the SoH and the material deterioration information, and
outputting the deterioration state as diagnosis results.
   [38]

The diagnosis method according to Item 37, wherein calculation of the deterioration state includes calculating a lithium deposition risk X of the storage battery based on information including the material deterioration information, and labeling a deterioration state of the storage battery based on one or a plurality of predetermined thresholds for each of the SoH and the lithium deposition risk X, and the diagnosis results include results of the labeling.

[39]

The diagnosis method according to Item 38, further comprising the step of displaying the output diagnosis results on a display part.

[40]

The diagnosis method according to Item 38 or 39, wherein the diagnosis method further comprises the step of controlling the storage battery based on results of the labeling.

[41]

A diagnosis program for a storage battery used in an energy storage system, the program causing a computer to execute the steps of:
acquiring charge/discharge data of the storage battery,
diagnosing material deterioration information of the storage battery obtained by inputting charge/discharge data of the storage battery into a trained model A which is trained so as to output material deterioration information of a storage battery when charge/discharge data is input, and
outputting the material deterioration information as diagnosis results.
   [42]

The diagnosis program according to Item 41, wherein the diagnosis program further causes a computer to execute the steps of:
estimating a state of health (SoH) of the storage battery based on charge/discharge data of the storage battery,
calculating a deterioration state of the storage battery based on the SoH and material deterioration information of the storage battery obtained by inputting charge/discharge data of the storage battery to a trained model A which is trained so as to output material deterioration information of a storage battery when charge/discharge data is input, and
outputting the deterioration state as diagnosis results.
   [43]

The diagnosis program according to Item 42, wherein the diagnosis program causes a computer to further execute the steps of calculating a lithium deposition risk X of the storage battery based on information including the material deterioration information, and labeling a deterioration state of the storage battery based on one or a plurality of predetermined thresholds for each of the SoH and the lithium deposition risk X, and the diagnosis results include results of the labeling.

[44]

The diagnosis program according to Item 43, wherein the diagnosis program causes a computer to further execute the step of displaying the output diagnosis results on a display part.

[45]

The diagnosis program according to Item 43 or 44, wherein the diagnosis program causes a computer to further execute the step of controlling the storage battery based on results of the labeling.

### Advantageous Effects of Invention

According to the present disclosure, there can be provided a storage battery deterioration diagnosis device, system, method, and program which enable more accurate storage battery deterioration diagnosis.

### BRIEF DESCRIPTION OF DRAWINGS

FIG. 1 is a view showing a schematic configuration of a diagnosis system 1 according to an embodiment.

FIG. 2 is a view showing a schematic configuration of an ESS 10.

FIG. 3 is a view showing a schematic configuration of a storage battery stack 200.

FIG. 4 is a view showing a schematic configuration of a local BMS 300.

FIG. 5 is a view showing a schematic configuration of a cloud BMS 400, as a diagnosis device and server which can be combined with the local BMS 300 of FIG. 4.

FIG. 6 is a flowchart showing an example of operations of learning processing of a trained model A.

FIG. 7 is a flowchart showing an example of operations of learning processing of a trained model B.

FIG. 8 is a flowchart showing an example of operations of diagnosis processing.

FIG. 9 is a flowchart showing an example of operations of calculation and control processing of lithium deposition risk X.

FIG. 10 is a flowchart showing an example of operations of calculation and label processing of lithium deposition risk X.

FIG. 11 is a flowchart showing an example of operations for predicting future lithium deposition risk X.

FIG. 12 is a flowchart showing an example of processing for labeling the deterioration state of a storage battery based on future lithium deposition risk X.

FIG. 13 is a flowchart showing an example of operations of control processing of a storage battery based on diagnosis results.

FIG. 14 is a flowchart showing an example of operations of control processing of a storage battery based on diagnosis results and a target operation period.

FIG. 15 is a view showing a schematic configuration of a cloud BMS 400, as a diagnosis device and server which can be combined with the local BMS 300 of FIG. 4.

FIG. 16 is a view showing a schematic configuration of a local BMS 300.

FIG. 17 is a view showing a schematic configuration of a cloud BMS 400, as a diagnosis device and server which can be combined with the local BMS 300 of FIG. 16.

FIG. 18 is a view showing a schematic configuration of a local BMS 300 as a diagnosis device.

FIG. 19 is a view showing a schematic configuration of a cloud BMS 400, as a server which can be combined with the local BMS 300 of FIG. 18.

### DESCRIPTION OF EMBODIMENTS

The deterioration diagnosis device, system, method, and program according to one aspect of the present disclosure will be described below with reference to the drawings. However, it should be noted that the technical scope of the present invention is not limited to these embodiments, but extends to the inventions set forth in the claims and their equivalents.

### <<Diagnosis System and Diagnosis Device>>

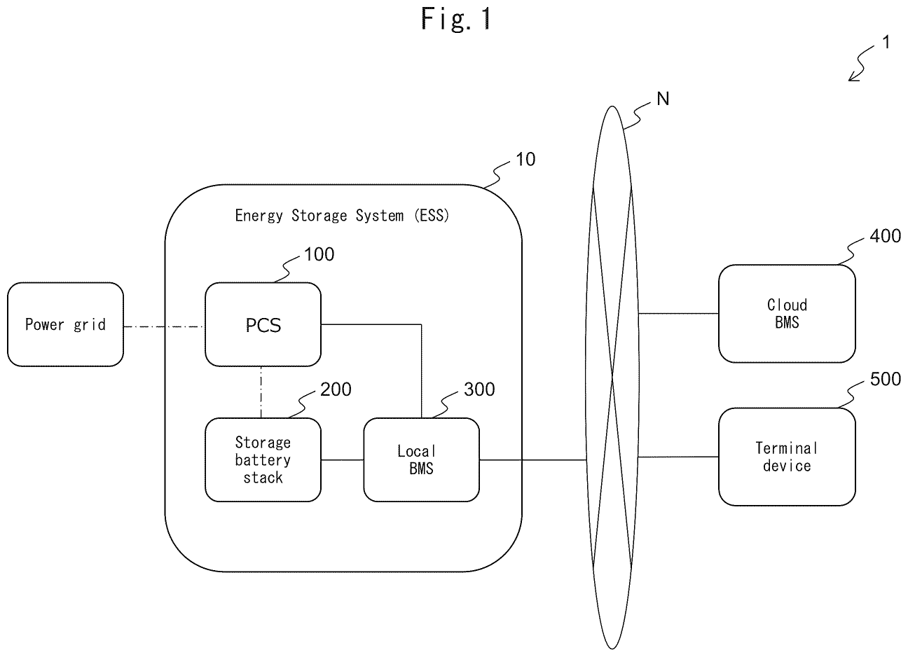

FIG. 1 is a view showing a schematic configuration of a diagnosis system 1 according to an embodiment. As shown in FIG. 1, the diagnosis system 1 comprises one or a plurality of ESSs 10, a cloud BMS 400, one or a plurality of terminal devices 500, etc. In FIG. 1, the connections indicated by dash-dotted lines represent electrical connections, and the connections represented by solid lines represent communicative connections. The ESS 10 comprises a power conditioner (PCS) 100 including a power converter which is electrically connected to a power grid, a storage battery stack 200 which is electrically connected to the PCS, and a local BMS 300 which is communicatively connected to the PCS and the storage battery stack. The local BMS 300, the cloud BMS 400, and the terminal device 500 are communicatively connected to each other via a network N. The network N is a wired network such as the Internet or an intranet. The network N may also be a wireless network such as a wireless LAN (Local Area Network).

### <Energy Storage System (ESS)>

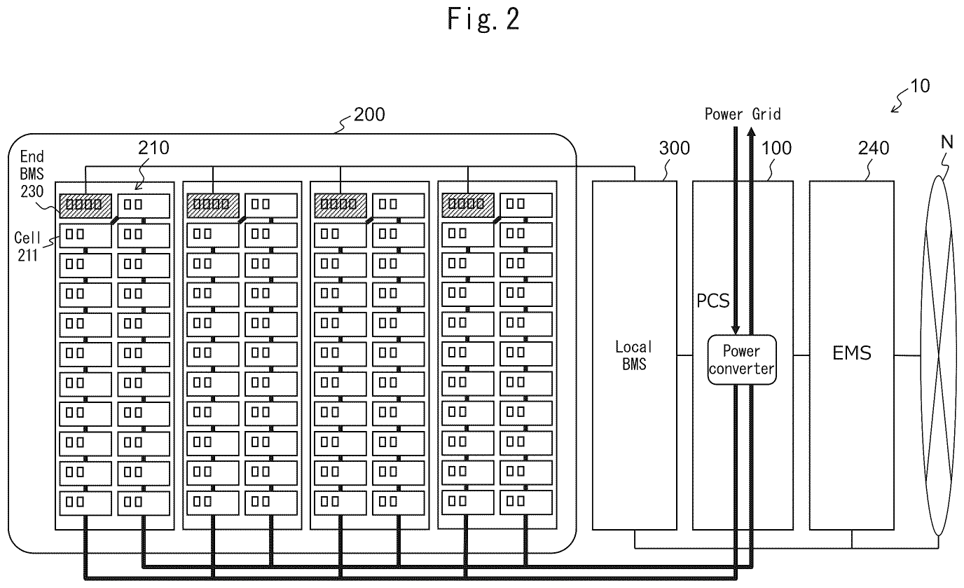

FIG. 2 is a view showing a schematic configuration of the ESS 10. As shown in FIG. 2, the ESS 10 comprises the PCS 100 and the storage battery stack 200, which is electrically connected to a power grid, the local BMS 300, which is communicatively connected to the PCS 100 and the storage battery stack 200, and an energy management system (EMS) 240. Typically, the PCS 100, the storage battery stack 200, the local BMS 300, and the EMS 240 are housed in a single container. In FIG. 2, the connections indicated by thick solid lines represent electrical connections, and the connections indicated by thin solid lines represent communicative connections.

The storage battery stack 200 comprises a one or a plurality of storage battery modules 210 arranged in series and/or parallel, each comprising a plurality of storage batteries (cells 211) arranged in series and/or parallel, and an end BMS 230 which is connected (not illustrated) to sensors of each storage battery and which is for performing tasks such as acquiring charge/discharge data. The plurality of storage batteries constituting a single storage battery module are typically connected in series, and the plurality of storage battery modules are connected in parallel to each other.

The power grid is connected to power supply sources, loads (power consumers), and facilities (not illustrated) for performing power transformation, power transmission, power distribution, power smoothing, etc. Examples of power supply sources include power generation facilities such as wind power generation and solar power generation. Examples of loads include power consumers such as offices, homes, commercial facilities, and factory facilities, as well as power consuming devices such as electric vehicles.

### <Power Conditioner (PCS)>

In FIG. 2, the PCS 100 has the function of adjusting the power charged and discharged to and from the storage battery. The PCS 100 may be of any form as long as it is functionally commonly used. Since power grids are generally controlled with alternating current (AC) and the storage battery stack 200 is controlled with direct current (DC), the PCS typically includes a power converter for performing AC-DC conversion. When the power on the power grid side is DC, the power converter is a converter for performing DC-DC conversion. The PCS can change the charge/discharge conditions of the storage battery stack 200 in response to external charge/discharge condition instructions, including maintaining, changing, or terminating the charge/discharge conditions. The charge/discharge condition instructions may be received directly from the local BMS 300 or an energy management system (EMS), or indirectly from the cloud BMS 400 via the network N.

### <Energy Management System (EMS)>

In FIG. 2, the EMS 240 is communicatively connected to the local BMS 300 and the PCS 100. The EMS is communicatively connected to a power supply source and a load (not illustrated) via the network N, and outputs charge/discharge condition instructions to the PCS in accordance with the amount of power generated by the power supply source and the state of the load, thereby controlling the input/output of energy between the power supply source, the load, and the ESS. The EMS may also be communicatively connected to the cloud BMS 400 via the network N and receive charge/discharge condition instructions from the cloud BMS 400. The EMS can control the local BMS 300 and/or the PCS 100 based on the received charge/discharge condition instruction.

### <Storage Battery Stack>

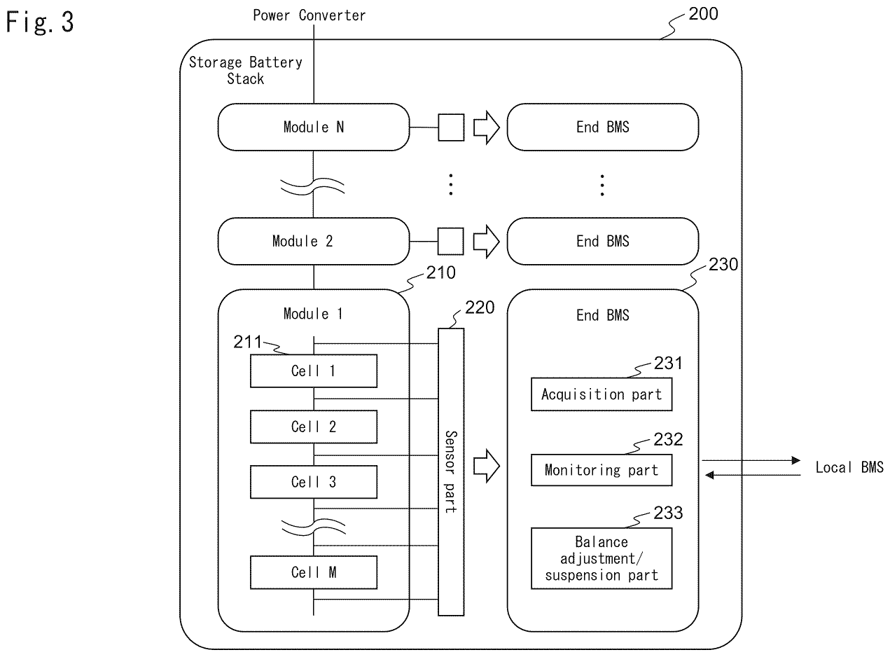

FIG. 3 is a view showing a schematic configuration of the storage battery stack 200. The storage battery stack 200 has the function of receiving charge and discharge of DC power provided by the power converter of the PCS 100 and storing and discharging electrical energy. The storage battery stack 200 comprises one or a plurality of storage battery modules 210 including one or a plurality of storage batteries (cells 211), a sensor part 220 for measuring charge/discharge data from the storage batteries constituting each storage battery module, and an end BMS 230 which connected to each storage battery module.

The storage battery is a secondary battery which can be repeatedly charged and discharged, such as a lithium-ion secondary battery (LiB), a lead storage battery, or a nickel-metal hydride secondary battery, and is preferably an LiB. LiBs can exhibit high energy density and high output, thereby reducing the size and cost of the ESS. Any type of LiB may be used as long as it operates in accordance with the principle of lithium-ion secondary batteries. Examples thereof include ternary lithium-ion secondary batteries (NCM111), high-nickel lithium-ion secondary batteries (NCM811, NCM622, NCM523), iron phosphate lithium-ion secondary batteries (LFP), and manganese lithium-ion secondary batteries. From the perspective of high capacity, NCM-based and high-nickel-based batteries, which have high energy density, are preferable, and from the perspective of safety, LFP-based batteries, which have stable positive electrode materials, are preferable.

The end BMS 230 comprises an acquisition part 231 for acquiring charge/discharge data from the sensor parts, a monitoring part 232 (IC) for monitoring the charge/discharge status of the storage batteries, and a balance adjustment/suspension part 233 which can balance (equalize) the SoC of the storage batteries and change the charge/discharge conditions, such as stopping charge/discharge. The balance adjustment/suspension part 233 is a current circuit mechanism which, upon receiving a command from the local BMS 300, can equalize the SoC among the plurality of storage batteries by, for example, dissipating the power of a storage battery having a high SoC as heat from a resistor, and can stop charge/discharge of the storage batteries in response to a charge/discharge stop command from the local BMS. Charge/discharge condition instructions from the cloud BMS 400 are transmitted to the EMS 240 and then to the local BMS 300 via the network N, or transmitted to the local BMS 300 via the network N. The local BMS 300 controls each end BMS 230 based on the charge/discharge condition instructions, thereby controlling the charge/discharge conditions of the storage batteries. The end BMS is also generally referred to as a cell management unit (CMU).

Examples of the charge/discharge data measured by the sensor part include the voltage, current, and temperature of a storage battery, the change over time thereof, and mathematically processed data thereof. More specifically, examples of the charge/discharge data include the voltage change over time (dOCV/dt-t plot) when charging of a storage battery is paused immediately after charging to an arbitrary SoC, the voltage change over time (V-t plot) during pulse charging and/or discharging at a constant current, the current change over time (I-t plot) observed during constant voltage charging, charge capacity and discharge capacity at a constant current or constant power, measurement data obtained by the AC impedance method, and mathematically processed data thereof. By using charge/discharge data acquired during actual operation of the ESS, material deterioration information can be inferred with even greater accuracy. For example, this data may be related to the voltage, current, and temperature when the storage batteries are charged or discharged due to operations such as inertial force or frequency adjustment in a stationary energy storage system, response to instantaneous voltage drops, peak shifting, or arbitrage. Alternatively, the charge/discharge data may be data obtained from charging and discharging in accordance with a charge/discharge program separately designated for the inspection and maintenance of the ESS, apart from the normal operation conditions of the ESS.

Measurement of the charge/discharge data in the sensor part may be carried out by any method. For example, when measuring voltage, the terminals of a voltage sensor can be attached to the positive and negative electrode terminals of the target storage battery. When measuring current, an ammeter can be attached to the target wiring. When measuring temperature, a temperature sensor can be attached to the target storage battery. The measurement resolution of voltage, current, and temperature may be any resolution which can be measured with a general sensor, and, for example, 8 bit, 12 bit, 16 bit, or 24 bit can be used. The measurement accuracy and sampling interval of the charge/discharge data can be arbitrarily set in accordance with a feature value related to the material deterioration information to be acquired (hereinafter referred to as electrochemical feature value). For example, when the acquisition of the direct current internal resistance (DCIR) of a storage battery is desired, a short sampling interval is preferable, for example, 1 msec or longer and 100 msec or shorter. Furthermore, in measurements at a low C rate such as the SoC-OCV curve of a storage battery, the sampling interval may be relatively long, preferably, for example, 100 msec or longer and 10 sec or shorter.

The end BMS 230 acquires the charge/discharge data of the storage battery measured by the sensor part and transmits it directly to the local BMS 300 via a wired or wireless connection. Alternatively, the charge/discharge data may be transmitted to the local BMS 300 via the network N.

### <Local BMS>

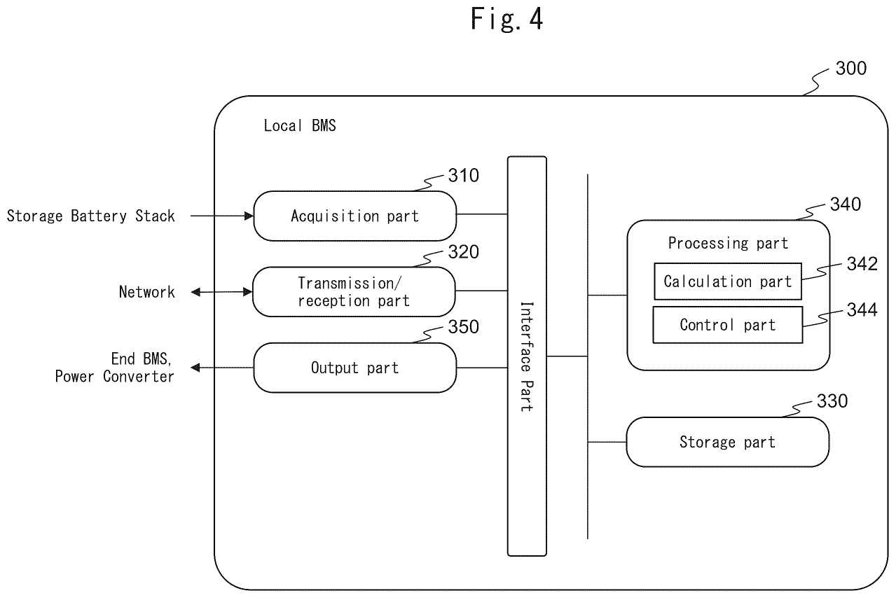

FIG. 4 is a view showing a schematic configuration of the local BMS 300. As shown in FIG. 4, the local BMS 300 comprises an acquisition part 310, a transmission part (transmission/reception part 320), a reception part (transmission/reception part 320), a storage part 330, a calculation part 342, a control part 344, and an output part 350. The acquisition part, the transmission/reception part, the storage part, the calculation part, the control part, and the output part are connected to each other via buses, interface parts, etc.

### Acquisition Part:

The acquisition part 310 acquires the charge/discharge data of the storage battery from the end BMS 230. The acquisition part 310 may acquire the charge/discharge data directly from the end BMS 230 via a wired or wireless connection, or may acquire (receive) the charge/discharge data from the end BMS 230 via the network N. The acquired charge/discharge data is stored in the storage part 330.

### Transmission/Reception Part:

The transmission/reception part 320 includes a wired communication interface circuit compliant with a communication protocol such as Transmission Control Protocol/Internet Protocol (TCP/IP), and is communicatively connected with the network N in accordance with a communication standard such as Ethernet®. The transmission/reception part 320 may also include an antenna for transmitting and receiving wireless signals, and a wireless communication interface circuit compliant with a communication protocol such as wireless LAN, and which is communicatively connected with the network N in accordance with a communication standard such as wireless LAN.

The transmission part (transmission/reception part 320) transmits the charge/discharge data of the storage battery to the cloud BMS 400, serving as the diagnosis device, via the EMS 240. The transmission part (transmission/reception part 320) may transmit the charge/discharge data of the storage battery to the cloud BMS 400 without passing through the EMS. When the calculation part 342 of the local BMS 300 calculates the SoH, SoC, SoP, SoS, etc., the transmission part may transmit the calculated SoH, etc., to the cloud BMS 400, likewise with or without passing through the EMS.

The reception part (transmission/reception part 320) can receive the charge/discharge condition instructions and the like transmitted from the cloud BMS 400 with or without passing through the EMS. The received charge/discharge condition instructions and the like are stored in the storage part 330 and are used to control the charge/discharge conditions of the storage battery. This transmission and reception include transmission and reception via a wired or wireless connection, and transmission and reception via the network N (the same applies below).

### Storage Part:

The storage part 330 comprises a memory device such as random access memory (RAM) or read-only memory (ROM), a fixed disk device such as a hard disk, or a portable storage device such as a flexible disk or optical disk. The storage part 330 can store computer programs used for various processes of the local BMS 300, acquired charge/discharge data, calculated SoH, SoC, SoP, and SoS, etc. The computer programs may be installed on the storage part 330 from a computer-readable portable recording medium using a known setup program or the like. The portable recording medium is, for example, a compact disc read-only memory (CD-ROM) or a digital versatile disc read-only memory (DVD-ROM). The computer programs may be stored in a recording medium owned by a specific server and installed via the network N.

### Processing Part:

The processing part 340 operates based on a program stored in the storage part 330 in advance. The processing part 340 is, for example, a CPU. The processing part 340 may be a digital signal processor (DSP), a large scale integration (LSI), an application specific integrated circuit (ASIC), a field-programmable gate array (FPGA), etc. The processing part 340 may comprise the calculation part 342 and the control part 344, is connected to the acquisition part, the transmission/reception part, the storage part, the output part, etc., and controls each functional part.

The calculation part 342 may calculate the SoH, SoC, SoP, SoS, etc., from the charge/discharge data of the storage battery. In this aspect, the calculated SoH, etc., are transmitted to the cloud BMS 400, serving as the diagnosis device, and used to calculate diagnosis results in the cloud BMS 400. The method of calculating the SoH will be described in detail later.

The control part 344 controls the storage battery based on the charge/discharge condition instruction received from the cloud BMS 400. More specifically, the control part 344 controls the ESS by transmitting the received charge/discharge condition instruction to the PCS 100 or the end BMS 230 via the output part 350. The control method will be described in detail later.

### Output Part:

The output part 350 outputs (transmits) the charge/discharge condition instruction from the control part 344 to the PCS 100 and/or the end BMS 230. When the local BMS 300 receives the SoH, material deterioration information, storage battery deterioration state, labeling results, current and future lithium deposition risk X, etc. (hereinafter referred to as “diagnosis results, etc.”) from the cloud BMS 400, the output part 350 may output (transmit) the received diagnosis results, etc., to a user terminal device 500, which includes a display part. The transmission of diagnosis results, etc., to the terminal device 500 can be performed from the transmission part via a network. The local BMS 300 may further comprise a display part (not illustrated), and in this case, the output part 350 may output (display) the diagnosis results, etc., to the display part.

The display part comprises a display including a liquid crystal display, an organic electroluminescence (EL) display, etc., and an interface circuit for outputting image data to the display, whereby the diagnosis results, etc., can be visually displayed on the display. As a result, the deterioration state of the storage batteries, the lithium deposition risk, etc., can immediately be grasped at the ESS operation site.

### <Cloud BMS>

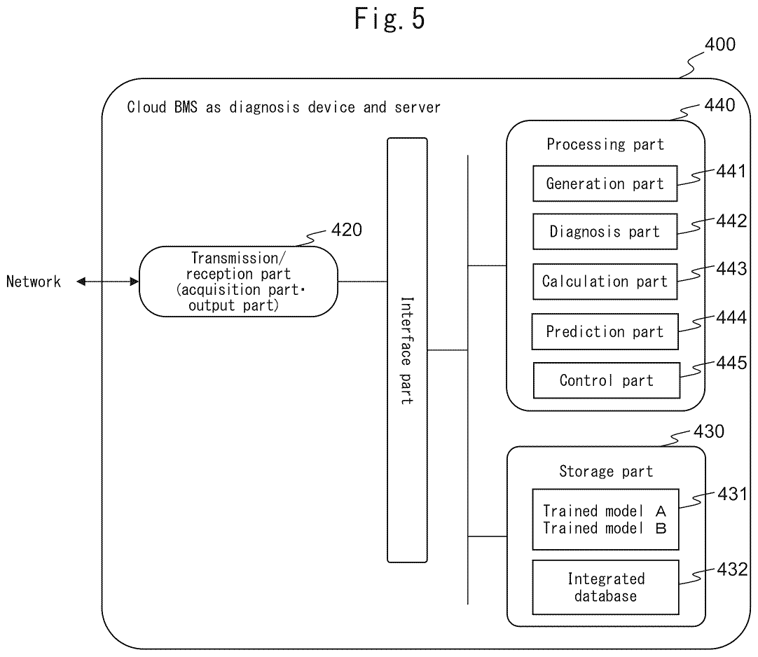

FIG. 5 is a view showing the schematic configuration of the cloud BMS 400, serving as the diagnosis device and server, which can be combined with the local BMS 300 of FIG. 4. The cloud BMS 400 functions as the diagnosis device and server, generating and updating a trained model, diagnosing deterioration using the trained model, and outputting the deterioration diagnosis. The cloud BMS 400 comprises an acquisition part (the reception part of a transmission/reception part 420), a storage part 430, a diagnosis part 442, a calculation part 443, a prediction part 444, a control part 445, and an output part (the transmission part of the transmission/reception part 420). The transmission/reception part, the storage part, the diagnosis part, the calculation part, the prediction part, and the control part are interconnected via buses, interfaces, etc. The server may be composed of a single server or a plurality of servers interconnected via the network N.

### Transmission/Reception Part:

The transmission/reception part 420 includes a wired communication interface circuit compliant with a communication protocol such as Transmission Control Protocol/Internet Protocol (TCP/IP), and is communicatively connected with the network N in accordance with a communication standard such as Ethernet®. The transmission/reception part 420 may also include an antenna for sending and receiving wireless signals, and a wireless communication interface circuit compliant with a communication protocol such as wireless LAN, and which is communicatively connected with the network N in accordance with a communication standard such as wireless LAN.

### Acquisition Part:

The acquisition part (the reception part of the transmission/reception part 420) acquires (receives) charge/discharge data of the storage battery from the local BMS 300. The acquisition part may also receive the SoH, SoC, SoP, SoS, etc., calculated (estimated) by the local BMS 300 based on the charge/discharge data. The acquired charge/discharge data and SoH, etc., are stored in the storage part 430.

### Storage Part:

The storage part 430 comprises a memory device such as Random Access Memory (RAM) or Read-Only Memory (ROM), a fixed disk device such as a hard disk, or a portable storage device such as a flexible disk or an optical disk. The storage part 430 stores a trained model 431, computer programs used for the various processing of the cloud BMS 400, acquired charge/discharge data, calculated SoH, SoC, SoP, and SoS, an integrated database 432, tables, etc. The computer programs may be installed into the storage part 430 from a computer-readable portable recording medium using a known setup program or the like. The portable recording medium is, for example, a compact disc read-only memory (CD-ROM) or a digital versatile disc read-only memory (DVD-ROM). The computer program may be stored in a recording medium owned by a specific server and installed via the network N.

The trained model 431 includes a trained model A which can identify one or a plurality of pieces of material deterioration information when charge/discharge data is input. The trained model 431 also includes a trained model B which outputs a future lithium deposition risk X trend when information including the SoH at the current time point, the lithium deposition risk Xt₁ at the current time point, and past charge/discharge data, and past SoH trends are input. The trained models A and B may each be composed of a single trained model, or preferably, are composed of a combination of a plurality of trained models which differ for each type of input charge/discharge data.

The integrated database 432 includes a dataset A containing one or a plurality of electrochemical feature values as training data obtained via experimentation and one or a plurality of pieces of material deterioration information associated therewith. The dataset A is used to generate and update the trained model A. The integrated database 432 also includes a dataset B containing charge/discharge data, SoH trends, and lithium deposition risk X trends, associated together as training data. The dataset B is used to generate and update the trained model B. The integrated database 432 is updated as needed by accumulating charge/discharge data of sampled storage batteries in various deterioration states, material deterioration information obtained by analyzing sampled storage batteries, SoH, and lithium deposition risk X. The trained model 431 becomes more accurate as more database data is collected in the integrated database 432. Details of the integrated database 432 will be described later.

### Processing Part:

The processing part 440 operates based on programs stored in advance in the storage part 430. The processing part 440 is, for example, a CPU. The processing part 440 may be a digital signal processor (DSP), a large scale integration (LSI), an application specific integrated circuit (ASIC), a field-programmable gate array (FPGA), etc. The processing part 440 comprises a generation part 441, a diagnosis part 442, a calculation part 443, a prediction part 444, and a control part 445, and is connected to the transmission/reception part, storage part, etc., for controlling each functional part.

The generation part 441 generates and re-trains the trained model 431 including the trained models A and B. Details of the training process will be described later.

The diagnosis part 442 diagnoses (identifies) the material deterioration information of a storage battery by inputting the charge/discharge data of the storage battery into the trained model A. When the charge/discharge data is input, the trained model A extracts one or a plurality of electrochemical feature values from the charge/discharge data and can identify one or a plurality of pieces of material deterioration information that are highly relevant to the extracted electrochemical feature values. Details of the diagnosis processing will be described later.

The calculation part 443 calculates the deterioration state of the storage battery based on information including the estimated SoH and the material deterioration information obtained from the trained model A. Conventionally, storage battery deterioration diagnosis was performed using parameters based only on charge/discharge data such as the SoH. However, the diagnosis device of the present disclosure combines the SoH with the material deterioration information inside the storage battery to more accurately diagnose the deterioration state of the storage battery. The SoH may be calculated by the calculation part 443 of the cloud BMS 400 based on the charge/discharge data of the storage battery acquired from the local BMS 300, or may be calculated by the calculation part 342 of the local BMS 300. When the calculation part 342 of the local BMS 300 calculates the SoH, the SoH is transmitted to the cloud BMS 400 together with the charge/discharge data. The calculation of the SoH will be described in detail later.

The calculation part 443 can calculate the lithium deposition risk X of the storage battery based on information including the material deterioration information inside the storage battery. The material deterioration information of the storage battery includes the material deterioration information of at least one selected from the group consisting of the positive electrode, the negative electrode, the separator, and the electrolyte of the storage battery. The calculation part 443 takes as input the information including the material deterioration information output from the diagnosis part, and calculates the lithium deposition risk of the corresponding storage battery as a numerical value (lithium deposition risk X). In addition to the material deterioration information, the information used to calculate the lithium deposition risk X can include charge/discharge data, material information of the storage battery, and the operation condition of the ESS. The material information of the storage battery includes the material information of at least one selected from the group consisting of the positive electrode, the negative electrode, the separator, and the electrolyte of the storage battery. Details of the method for calculating the lithium deposition risk X will be described later.

The calculation part 443 can label the deterioration state of the storage battery based on one or a plurality of predetermined thresholds for the estimated SoH and the lithium deposition risk X. Conventionally, storage battery deterioration diagnosis was performed using parameters based only on charge/discharge data such as SoH. However, the diagnosis device of the present disclosure can divide the deterioration state of the storage battery into a plurality of quadrants based on the SoH and the material deterioration information inside the storage battery, and label the storage battery according to the degree of deterioration. Thus, this aspect has the advantage of being able to more accurately and easily understand the deterioration state of the storage battery. Details of the labeling process will be described later.

The prediction part 444 predicts the future lithium deposition risk X trend by inputting information including the SoH at the current time point, the lithium deposition risk Xt₁ at the current time point, past charge/discharge data, and past SoH trends into the trained model B. The calculation part 443 can then label the deterioration state of the storage battery based on the information including the future lithium deposition risk X trend. Details of the prediction processing and labeling processing will be described later.

The control part 445 controls the charge/discharge conditions of the storage battery based on the diagnosis results. The diagnosis results include the deterioration state of the storage battery and may also include the labeling results of the storage battery. Based on the diagnosis results, the control part 445 can generate charge/discharge condition instructions, including maintaining, changing, or stopping the charge/discharge conditions. Details of the control processing will be described later.

### Output Part:

The output part (the transmission part of the transmission/reception part 420) outputs (transmits) the calculated deterioration state as diagnosis results to the terminal device 500 of the user. The diagnosis results include the deterioration state of the storage battery and may further include the SoH, material deterioration information, labeling results, and current and future lithium deposition risk X (“diagnosis results, etc.”). The output part may transmit the diagnosis results, etc., to the EMS 240 and/or the local BMS 300.

The output part (transmission/reception part 420) transmits the charge/discharge condition instruction generated from the control part 445 to the local BMS 300, either via the EMS 240 or without. The local BMS 300 controls the end BMS 230 based on the charge/discharge condition instruction, thereby controlling the charge/discharge conditions of the storage battery.

### <Terminal Device>

The terminal device 500 shown in FIG. 1 is a user terminal and may be, for example, an information processing device such as a personal computer, notebook PC, tablet PC, or multi-function mobile phone (so-called “smartphone”). The terminal device 500 comprises a reception part and a display part (not illustrated), which are interconnected via buses and an interface part. The reception part can receive diagnosis results, including the deterioration state of the storage battery, as well as the SoH, the material deterioration information, the labeling results, and current and future lithium deposition risk X (hereinafter referred to as “diagnosis results, etc.”) transmitted from the local BMS 300 or cloud BMS 400. The display part comprises a display, including a liquid crystal display (LCD) or organic electroluminescence (EL) display, and an interface circuit for outputting image data to the display, whereby the diagnosis results, etc., can be visually displayed on the display. As a result, the terminal device 500 can instantly notify the user of the diagnosis results, etc., of the storage battery installed in the currently operating ESS.

Examples of users include ESS operators, ESS suppliers, storage battery or storage battery material manufacturers, and storage battery recyclers. By instantly notifying the user of the diagnosis results, etc., the user can immediately identify issues related to the ESS operation conditions or storage battery specifications without disassembling and inspecting the storage battery. As a result, each user has the following advantages. ESS operators can develop highly predictive maintenance plans based on the deterioration state of the battery, enabling safe and efficient ESS operation. Furthermore, even if the diagnosis indicates that the battery requires immediate replacement and would otherwise require immediate ESS operation shutdown, ESS operation can be continued and planned maintenance can be performed by changing the charging and discharging conditions to safe conditions in consideration of the deterioration state of the battery. For example, if an ESS is used to operate equipment in a factory, etc., the operational efficiency of the ESS can be maximized by aligning the ESS battery replacement period with the scheduled repairs of the equipment. Furthermore, for example, the operational efficiency of an ESS can be maximized by controlling the optimal charge/discharge conditions of an operating storage battery in accordance with market conditions for new storage batteries or reused batteries (the timing of procurement of batteries with the desired performance and quantity). Furthermore, for example, profits from differences in electricity rates can be maximized by controlling the optimal charge/discharge conditions of an operating storage battery in accordance with fluctuations in the electricity rate market. ESS suppliers can devise ESS designs and operation conditions which extend the life of storage batteries based on diagnosis results, feed the diagnosis results back into the development of new ESSs, and identify ESSs or storage batteries which may be subject to recall more quickly. Furthermore, reducing the risk of lithium deposition in ESSs and/or extending their lifespans can reduce the frequency of ESS maintenance and limit overloading of storage batteries, which is expected to reduce the cost of storage batteries used in ESSs. Storage battery or storage battery material manufacturers can predict delivery dates for storage batteries or storage battery materials based on maintenance plans, enabling them to supply storage batteries or storage battery materials in a planned manner. Furthermore, diagnosis results, etc., can be fed back into the development of new storage batteries or storage battery materials, enabling the provision of higher-value products to each customer. Storage battery recyclers can determine in advance the delivery dates of batteries to be recycled based on a maintenance plan, as well as the delivery dates of replacement reused batteries, enabling them to create efficient recycling plans. Furthermore, the safety of batteries to be recycled and material deterioration information can be checked in advance, enabling safer and more efficient recycling operations.

### <<Learning Procedure>>

### <Learning of Trained Model A>

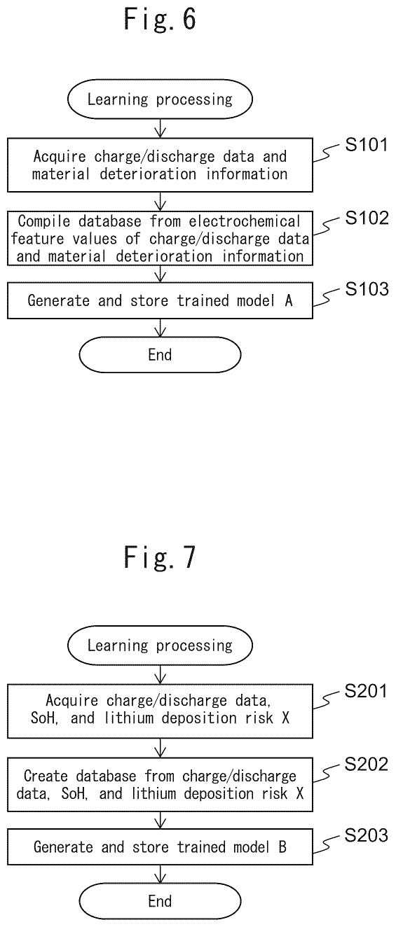

FIG. 6 is a flowchart showing an example of the operations of learning processing of the trained model A. The operation flow described below is executed primarily by the generation part 441 included in the processing part 440 of the cloud BMS 400 in cooperation with each element based on a program stored in advance in the storage part 430 of the cloud BMS 400.

Initially, the cloud BMS 400 acquires charge/discharge data and material deterioration information as training data for generating the trained model A (step S101). The training data preferably includes charge/discharge data of a storage battery of the same type as those used in the ESS to be diagnosed and controlled, and material deterioration information thereof. The charge/discharge data and material deterioration information as training data can be acquired by charging and discharging a storage battery that has been placed in various deterioration states via accelerated experimentation or the like, then dismantling the storage battery and visually, chemically, and physically analyzing each component, such as the positive electrode, negative electrode, separator, and electrolyte. Alternatively, training data can be obtained by receiving charge/discharge data of storage batteries in various deterioration states sampled from the ESS to be diagnosed and controlled from the local BMS, and then experimentally analyzing the sampled storage batteries to obtain material deterioration information. Details of experimentation will be described later.

Next, the electrochemical feature values of the charge/discharge data and the material deterioration information are compiled into a database (step S102). More specifically, electrochemical feature values are extracted from the charge/discharge data of the storage battery, and a dataset A in which the extracted electrochemical feature values are associated with the material deterioration information obtained by disassembling and analyzing the storage battery is created. In the integrated database 432, the dataset A is recorded as one or a plurality of tables in which these electrochemical feature values and material deterioration information are integrated.

Finally, a trained model A is generated based on the created tables and stored in the storage part 430 (step S103), and the series of steps ends. The trained model A can be generated by pre-training a machine learning model, such as a neural network or a support vector machine, using supervised learning. More specifically, when charge/discharge data is input, one or a plurality of electrochemical feature values are extracted from the charge/discharge data, and the model is pre-trained to identify one or a plurality of pieces of material deterioration information which are highly relevant to the extracted electrochemical feature values. When electrochemical feature values previously extracted from charge/discharge data are input, the model may be pre-trained to identify one or a plurality of pieces of material deterioration information which are highly relevant to the input electrochemical feature values. Details of the method for extracting electrochemical feature values will be described later. It is preferable that a different trained model be generated for each type of input charge/discharge data and a plurality of trained models be combined to construct a trained model A which can comprehensively identify one or a plurality of pieces of material deterioration information from one or a plurality of combinations of charge/discharge data.

### <Learning of Trained Model B>

FIG. 7 is a flowchart showing an example of the operation of learning processing of a trained model B. The operation flow described below is executed primarily by the generation part 441 included in the processing part 440 of the cloud BMS 400 in cooperation with each element based on a program stored in advance in the storage part 430 of the cloud BMS 400.

Initially, the cloud BMS 400 acquires charge/discharge data, an SoH estimated from the charge/discharge data, and a lithium deposition risk X calculated from the charge/discharge data through diagnosis processing using trained model A (step S201), which serve as training data for generating the trained model B. Details of estimation of the SoH and calculation of the lithium deposition risk X will be described later. The training data preferably includes charge/discharge data, etc., of a storage battery of the same type as the storage battery used in the ESS to be diagnosed and controlled. The charge/discharge data, etc., as training data can also be acquired by charging and discharging a storage battery that has been placed in various deterioration states through accelerated experimentation or the like in advance. Alternatively, the charge/discharge data, etc., as training data can also be obtained by receiving, from the local BMS, charge/discharge data of storage batteries in various deterioration states sampled from the ESS to be diagnosed and controlled.

Next, the acquired charge/discharge data, SoH, and lithium deposition risk X are compiled into a database (step S202). More specifically, the charge/discharge data, SoH trends, and lithium deposition risk X trends at various measurement points (deterioration states) from the initial stage of the storage battery until the end of life (replacement) thereof are acquired, and these are correlated to create the dataset B. In the integrated database 432, the dataset B is recorded as one or a plurality of tables in which the charge/discharge data, SoH trends, and lithium deposition risk X trends are integrated.

Finally, the trained model B is generated based on the created tables and is stored in the storage part 430 (step S203), and the series of steps ends. The trained model B can be generated by pre-training a machine learning model, such as a neural network or support vector machine, using supervised learning. More specifically, the trained model is pre-trained such that when an SoH and a lithium deposition risk X at a certain point in time, as well as information including past charge/discharge data and changes in SoH from that point in time, are input, the model will output a future lithium deposition risk X from that point in time onward. It is preferable to generate a different trained model for each type of input charge/discharge data and combine a plurality of trained models to create a trained model B which can comprehensively output a future lithium deposition risk X from one or a plurality of combinations of charge/discharge data.

### <<Integrated Database>>

The integrated database is a database including the dataset A, in which the electrochemical feature values of the charge/discharge data of the storage battery and the corresponding material deterioration information are integrated, and the dataset B, in which information including the charge/discharge data, SoH trends, and lithium deposition risk X trends are integrated. An example of the method for creating an integrated database in the case in which LiB is used as the storage battery is described below.

### <Dataset A>

### Electrochemical Feature Value Extraction:

First, LiBs in various deterioration states with known usage histories, such as charging and discharging, are prepared. To acquire the training data, preferably, the same type of LiBs as those used in the ESS to be diagnosed and controlled, and more preferably, LiBs which were actually used in the ESS to be diagnosed and controlled, are used. The deterioration state may be adjusted in various manners, such as through accelerated experimentation. These LiBs are charged and discharged, and the resulting charge/discharge data (for example, changes in current, voltage, and temperature over time) are acquired. The charge/discharge data for the storage battery can be obtained by electrically charging and discharging the storage battery using a commonly available charging/discharging device and recording the changes in voltage, current, and temperature over time obtained in response thereto. The charging/discharging device having voltage and current ranges which match the voltage (V) and current capacity (Ah) of the target storage battery, and capable of controlling the voltage and current and setting the charging/discharging conditions as desired, may be used. Examples thereof include the ACD-01 charge/discharge test equipment 5V/10 A (1 A)-12ch system (charge/discharge unit model: ACDS-10APS (01)-05N) manufactured by Asuka Electronics Co., Ltd., and the regenerative charge/discharge test equipment [5V 360 A 1.8 kW 6ch] manufactured by Fujitsu Telecom Network Limited.

The measured charge/discharge data includes, for example, the voltage change over time when the storage battery is charged to an arbitrary SoC and then charging is immediately paused (dOCV/dt-t plot), the voltage change over time during pulse charging and/or discharging at a constant current (V-t plot), the current value change over time observed during constant voltage charging (I-t plot), the charge capacity and discharge capacity at a constant current or constant power, measurement data obtained by the AC impedance method, and mathematically processed data thereof. Next, the obtained charge/discharge data is mathematically converted to extract features (electrochemical feature values) related to material deterioration information of the LiBs. Examples of electrochemical feature value extraction are given below.

(1) Voltage Change Over Time when Charging of Battery is Paused Immediately after Charging

As a method for electrochemically detecting Li metal deposition in LiB, Zachary M. Konz, et al., “Detecting the Onset of Lithium Plating and Monitoring Fast Charging Performance with The method described in “Voltage Relaxation,” American Chemical Society Energy Letters, (2020), 5(6), pp. 1750-1757 can be referenced. In this method, LiB discharged to SoC=0% is charged at a constant current (for example, C rate-3 C), charging is stopped at an arbitrary SoC, and the time course of voltage relaxation is measured when the LiB is left at rest in an unloaded state. When Li deposition occurs, the negative electrode contains Li metal and Li intercalated into graphite (C₆Li), and at this time, a plateau occurs as a mixed potential of the negative electrode. As a result, a plateau occurs in the cell voltage in an unloaded state immediately after charging (hereinafter referred to as the open circuit voltage, or OCV). Using this time trend of OCV (hereinafter also referred to as OCV-t plot), an electrochemical feature value related to Li metal deposition can be acquired. For example, a dOCV/dt-t plot in which dOCV/dt, which is the time derivative of the OCV-t plot, is plotted on the vertical axis and time t (sec) is plotted on the horizontal axis is created. As a result, when a plateau occurs in the OCV-t plot, the dOCV/dt-t plot will have a profile with a local maximum value. The presence or absence of this local maximum value (the point where d²OCV/dt²=0) and the time t (sec) at the local maximum value can be used as an electrochemical feature value. The presence of a local maximum value (the point where d²OCV/dt²=0) indicates the occurrence of a plateau, i.e., the presence of Li metal deposition. Furthermore, the longer the time t (sec) at the local maximum value, the longer the plateau, i.e., the more Li metal is precipitated.

(2) Voltage Change Over Time During Pulse Charging and/or Discharging at Constant Current

Analysis of voltage drop plots (for example, V-t plots) observed when applying constant-current pulse charging and/or discharging to LiB can provide information suggesting the state of Li metal deposition. When LiB is subjected to constant-current pulse charging or discharging at a relatively high C rate, abrupt voltage fluctuations (overvoltage) occur in accordance with Ohm's law (V=IR) due to the internal resistance of LiB. LiB overvoltage can be broadly divided into resistance overvoltage due to electronic resistance, activation overvoltage caused by chemical reactions occurring at the interface between the electrode active material and the electrolyte, and concentration overvoltage caused by the concentration gradient of ions moving through the electrolyte or electrode active material. Because these three types of overvoltage have different reaction rates, when voltage-time plots are used, the overvoltage changes over time. Roughly speaking, resistance overvoltage is observed in short time periods of 0.1 seconds or less, activation overvoltage in time periods of 0.1 to several seconds, and concentration overvoltage in long time periods of several to several thousand seconds. Since the reaction in which Li metal precipitates primarily corresponds to the activation overvoltage, by analyzing the trend of the overvoltage in the time region from 0.1 seconds to several seconds, it is possible to consider the precipitation of Li metal.

### (3) Voltage Change Over Time Observed During Constant Voltage Charging

The state of Li metal deposition can be analyzed by analyzing the time dependence of the current observed during constant-voltage charging of LiB at a high C rate (hereinafter referred to as the I-t plot). When Li deposition occurs during constant-voltage charging at a high C rate, the I-t plot demonstrates a behavior in which the current value reaches a local minimum value once, followed by a delayed gradual increase in the current value. This is because the charge applied to the LiB is consumed by Li metal deposition without being used to charge the positive and negative electrodes, temporarily reducing the convergence current value, and then by charging of the positive and negative electrodes with a delay, thus resulting in gradually increasing the convergence current value. The depth of the local minimum value (minimum current value: A) and the position (sec) thereof in the I-t plot can be used as electrochemical feature values. Note that when determining Li metal deposition, the voltage during constant-voltage charging is preferably performed in the high SoC region, where the negative electrode potential is low.

### (4) Charge/Discharge Efficiency (Coulomb Efficiency)

The charge/discharge efficiency during low-rate charging and discharging can be used as an electrochemical feature value. In this method, the charge/discharge efficiency of a target LiB can be obtained by dividing the discharge current capacity (Ah) obtained by discharging a LiB adjusted to SoC=100% at a constant current of 0.25 C by the charge current capacity (Ah) obtained by charging a LiB adjusted to SoC=0% at a constant current of 0.25 C. If a large amount of the charged current capacity is consumed by side reactions that do not actually contribute to charging, the discharge capacity will be small, and the charge/discharge efficiency will decrease. An example of a side reaction is the generation reaction of Li dendrites. Li dendrites may penetrate the separator, which serves to separate and insulate the positive and negative electrodes, causing an internal short circuit. Thus, the charge/discharge efficiency reflects information regarding internal short circuits of the LiB and is thus an important electrochemical feature value for determining the safety of LiBs. The lower the charge/discharge efficiency, the more Li metal is precipitated, suggesting the generation of Li dendrites.

### (5) Nyquist Plot

Electrochemical feature values can be obtained from a Nyquist plot obtained by electrochemical impedance spectroscopy (hereinafter also referred to as EIS). For example, an FRA module (module code: 1455) for cell test systems manufactured by SOLARTRON ANALYTICAL can be used to measure EIS. In this method, a Nyquist plot is created by sweeping, for example, a range from 20 kHz to 0.1 Hz for an LiB adjusted to an arbitrary SoC, and acquiring the response data. From the Nyquist plot, inductance (H), capacitance (F), and DC resistance (Ω) corresponding to an equivalent circuit model of the LiB, which can be attributed to the material components inside the LiB, can be acquired. For example, if Li metal is precipitated, the component attributed to Li metal can be extracted as its parasitic impedance, and this can be used as an electrochemical feature value.

Though there are several methods for acquiring electrochemical feature values related to the safety of LiB, and in particular, Li metal deposition, as described above, the electrochemical feature values are not limited to these.

### Acquisition of Material Deterioration Information:

Material deterioration information as training data can be acquired by disassembling LiBs in various deterioration states after completing the charging and discharging operations required to acquire the electrochemical feature values described above, and extracting and analyzing the internal materials (positive electrode, negative electrode, electrolyte, separator, etc.) thereof. It is preferable to collect information regarding various deterioration states for each type of storage battery prepared for training data acquisition. Thus, it is preferable to prepare a large number of storage batteries in various deterioration states by conducting accelerated experimentation such as cycle tests, high-temperature storage tests, and float tests. Furthermore, by using the results of analysis of the constituent materials of the LiBs obtained by acquiring and disassembling LiBs actually used in ESS operation, material deterioration information can be inferred with even greater accuracy. For example, when LiBs are charged and discharged due to operations such as inertial force or frequency adjustment, response to momentary voltage drops, peak shifting, or arbitrage in a stationary energy storage system, defective LiBs can be extracted, disassembled, and analyzed, and the resulting material deterioration information can be used.

The method for dismantling an LiB may be any method depending on the shape of the LiB (cylindrical, laminated, square, etc.). Generally, LiBs can be dismantled by peeling off the exterior material with general-purpose tools (nippers, scissors, etc.), removing the internal electrode assembly (a laminated or wound structure of a positive electrode, a negative electrode, and a separator), and then separating the electrode assembly into its individual components.

Prior to analysis, the disassembled positive electrode, negative electrode, and separator are preferably subjected to pretreatment processing in which they are washed with a solvent to remove any non-immobilized material on the surface thereof. The solvent used should be one which is capable of washing away any electrolyte adhering to the surface, and for example, carbonate solvents such as dimethyl carbonate, ethyl methyl carbonate, and diethyl carbonate are preferable. For example, the sample is immersed in a diethyl carbonate solvent in an amount 50 to 100-fold the weight of the sample for 10 minutes or longer, after which the solvent is replaced and the sample is immersed again. The sample is then removed from the diethyl carbonate and vacuum-dried (temperature: 0 to 200° C., pressure: 0 to 20 kPa, time: 1 to 40 hours, under conditions such that the remaining diethyl carbonate in the sample is 1 mass % or less).

Next, visual, physical, and chemical analyses are performed on the pretreated positive electrode, negative electrode, and separator, and the acquired information can be used as LiB material deterioration information. For example, in visual analysis, surface images of the positive electrode, negative electrode, and separator are acquired using a digital camera, scanning electron microscope (SEM), transmission electron microscope (TEM), etc., and the images are analyzed using binarization and color tone analysis, etc., to obtain information regarding the area, distribution, and shape of by-products formed due to storage battery deterioration. Examples of physical analyses include, for example, observing the weight of by-products formed on the positive electrode, negative electrode, and separator as a difference from the weight of the material before deterioration. Examples of chemical analyses include structural analysis of the active materials, etc., using X-ray diffraction (XRD) for the positive electrode, negative electrode, and separator, and analyzing the chemical state of the materials constituting the components using X-ray photoelectron spectroscopy (XPS), nuclear magnetic resonance (NMR), electron spin resonance (ESR), etc.

When an LiB is used as a storage battery, the material deterioration information preferably includes information regarding the deposition of Li metal on the negative electrode, which is directly related to the safety of LiB. More specifically, the material deterioration information includes the area, the shape of the deposition region, the deposition weight, the distribution state, and the color tone of the deposited lithium metal analyzed from an image of the negative electrode surface of the storage battery, the shape of the lithium metal observed by cross-sectional SEM observation of the negative electrode, the chemical shift value (eV) and/or the area thereof obtained from the Li (s1) spectrum obtained by XPS analysis, the chemical shift value (ppm) and/or the area thereof obtained from the ⁷Li-NMR spectrum, and the chemical state expressed by the g value and/or line width obtained from the ESR spectrum.

### (1) Image Analysis of Li Metal Formed on Negative Electrode

As an example of material deterioration information, an example of image analysis of Li metal formed on a negative electrode is given. However, image analysis is not limited to the state of Li metal on the negative electrode, and image analysis can be performed on any image, such as the collapse of the positive electrode active material, SEI formed on the negative electrode surface, and black spot evaluation on the separator.

First, the negative electrode, which has been disassembled and pre-treated using the above method, is photographed with a camera which detects visible light, such as a digital camera, single-lens reflex camera, or smartphone camera. Graphite is typically used as the active material for LiB negative electrodes. Li ion-doped graphite (C₆Li) is typically yellow, while the regions where Li metal is deposited typically exhibit a white, gray, or silver color with a metallic luster. Next, the photographed image of the negative electrode surface is analyzed to acquire information such as the presence or absence of Li metal deposition, the area of the deposition region, and the quality of the deposited Li metal. For example, the morphology of Li metal deposition on the negative electrode surface may include the formation of island-like Li metal deposition regions on the surface of the negative electrode. In this case, an image showing island-like white regions on a yellow background is obtained. The image is then processed using binarization analysis or another method, and information such as the presence or absence of Li metal deposition regions, the deposition area, and the deposition shape can be analyzed from the color difference and area. Furthermore, information regarding the quality of the deposited Li metal can be acquired from the color tone of the Li metal deposition region. For example, plate-shaped Li metal has a bright color tone with the inherent metallic luster of Li metal when observed with the naked eye, but Li dendrites, which can cause internal short circuits, have a fine and complex tree-like structure, and thus, appear dark gray to the naked eye. Information regarding the deposited Li metal obtained from these areas and color tones can be obtained by computer analysis at a level equivalent to that of visual judgment using a trained model which has undergone machine learning or deep learning on the acquired image and images processed by binarization analysis, color tone analysis, etc.

Since image analysis is influenced by the conditions under which the image was captured, it is desirable to maintain constant conditions during image capture. The conditions include, for example, the charging state of the LiB when the negative electrode is acquired, the conditions for preparing the negative electrode, such as the cleaning and drying state of the negative electrode, as well as the conditions during image capture, such as the color and luminous intensity of the light source in the image capture environment, magnification and contrast, color tone correction, and the distance and angle between the camera and the negative electrode.

### (2) Scanning Electron Microscopy (SEM)

SEM observation allows for observation of the microscopic morphology of by-products formed primarily on the surface of materials. Furthermore, by combining it with energy dispersive X-ray analysis (EDX), qualitative elemental analysis of the structures formed on the surface can be performed. Furthermore, mapping the elemental analysis results allows for the observation of the spatial distribution state of surface elements. An example of material degradation state is the observation of the morphology of Li metal formed on the negative electrode surface. When LiB is charged, Li ions cannot be absorbed within the negative electrode active material, and Li metal precipitates on the negative electrode surface. The morphology of the precipitated Li metal influences the risk of internal short circuits in LiB. Generally, dendritic Li metal increases the risk of short-circuiting of the positive and negative electrodes via microscopic holes in the separator. Thus, understanding the morphology of Li metal through SEM observation allows for estimation of the risk of internal short circuits.

A specific example of the SEM observation method is shown below. First, the surface of the negative electrode is coated with a gold film having a thickness of several nanometers by sputtering gold in a vacuum of 10 Pa. Next, an SEM image of the surface of the negative electrode active material layer can be captured under atmospheric exposure under the conditions shown below.

### (SEM Measurement Conditions)

Measurement equipment: Hitachi High-Technologies Corporation, field emission scanning electron microscope S-4700
Acceleration voltage: 1 kV
Emission current: 10 μA
Measurement magnification: 20,000-fold
Detector: Secondary electron detector
Electron beam incident angle: 90°

When capturing the image, it is preferable to adjust the brightness and contrast so that there are no pixels which reach the maximum brightness value in the SEM image and the average brightness value is within the range of 40% to 60% of the maximum brightness value.

### (3) X-Ray Photoelectron Spectroscopy (XPS)

The bonding state of lithium can be determined by analyzing the electronic state of lithium using XPS. Measurement conditions therefor include, for example, a monochromated AlKα X-ray source, a 100 μmφ X-ray beam diameter (25 W, 15 kV), a narrow scan pass energy of 58.70 eV, charge neutralization, narrow scan sweeps of 10 (carbon, oxygen), 20 (fluorine), 30 (phosphorus), 40 (lithium), and 50 (silicon), and a narrow scan energy step of 0.25 eV. It is preferable to clean the surface of the positive electrode by sputtering before XPS measurement. For example, the sputtering conditions include an acceleration voltage of 1.0 kV, a 2 mm×2 mm area, and a 1-minute sputtering rate (1.25 nm/min in terms of SiO₂). In the obtained XPS spectrum, preferably, the peak at a Li1s binding energy of 50 to 54 eV is attributed to LiO₂ or Li—C bond, the peak at 55 to 60 eV is attributed to LiF, Li₂CO₃, LiₓPO_{y}F_{z} (where x, y, z are integers of 1 to 6), the peak at a C1s binding energy of 285 eV is attributed to C—C bond, the peak at 286 eV is attributed to C—O bond, the peak at 288 eV is attributed to COO, the peak at 290 to 292 eV is attributed to CO₃²⁻ and C—F bond, the peak at an O1s binding energy of 527 to 530 eV is attributed to O²⁻(Li₂O), the peak at 531 to 532 eV is attributed to CO, CO₃, OH, POₓ (where x is an integer from 1 to 4), SiOₓ (where x is an integer of 1 to 4), the peak at 533 eV is attributed to C—O and SiOₓ (where x is an integer of 1 to 4), the peak at an F1s binding energy of 685 eV is attributed to LiF, the peak at 687 eV is attributed to C—F bond, LiₓPO_{y}F_{z} (where x, y, z are integers from 1 to 6), PF₆⁻, the peak at a P2p binding energy of 133 eV is attributed to POₓ (where x is an integer from 1 to 4), the peak at 134 to 136 eV is attributed to PFₓ (where x is an integer from 1 to 6), the peak at a Si2p binding energy of 99 eV is attributed to Si, silicide, and the peak at 101 to 107 eV is attributed to SiₓO_{y} (where x and y are arbitrary integers). When peaks overlap in the obtained spectrum, it is preferable to separate the peaks by assuming a Gaussian function or a Lorentzian function and assign the spectrum. The chemical state of the lithium present can be determined from the results of the measurement of the electronic state and the results of the ratio of the elements present obtained above.

### (4) Nuclear Magnetic Resonance (NMR)

NMR can provide chemical information regarding the components of the positive electrode, negative electrode, separator, and electrolyte. As an example, a measurement method for ⁷Li in a negative electrode will be described. First, a composite layer is collected from the negative electrode after the pretreatment described above and weighed. Next, solid-state ⁷Li-NMR measurement is performed on the resulting negative electrode composite layer. A JEOL RESONANCE ECA700 (the ⁷Li-NMR resonance frequency is 272.1 MHz) as an example of a measurement device can be mentioned. Measurement is performed at room temperature using the single-pulse method with a magic-angle spinning speed of 14.5 kHz and an irradiation pulse width of 45°. A 1 mol/L lithium chloride aqueous solution is used as the shift reference, and the shift position measured separately as an external standard is defined as 0 ppm. When measuring the lithium chloride aqueous solution, the sample is not rotated, and measurement is performed using the single-pulse method with an irradiation pulse width of 45°. During measurement, a sufficient waiting time between measurements is necessary, and the waiting time is set to 3000 seconds. The solid-state ⁷Li-NMR spectrum of the negative electrode composite layer obtained using this method allows us to understand the chemical state of Li. For example, in the case of Li metal, which poses a risk of ignition, the chemical shift occurs around 270 ppm. Conversely, in the case of solid electrolyte interfaces (SEIs) such as SEIs, which do not lead to ignition of the LiB, the shift occurs around 0 ppm.

Though examples of specific methods for acquiring material deterioration information have been described above, the material deterioration information is not limited to these items and methods.

### Other Information:

It is preferable that the dataset A include information on each component used in the LiB, associated with the electrochemical feature values and material deterioration information described above. As a result, the trained model A can identify material deterioration information with even higher accuracy. Examples of component information include positive electrode manufacturing conditions and negative electrode manufacturing conditions. Positive electrode manufacturing conditions include the basis weight (g/m²) of the positive electrode active material layer, the thickness (μm) of the positive electrode active material layer, the bulk density (g/cc) of the positive electrode active material layer, the type and amount (mass %) of the positive electrode active material in the positive electrode active material layer, the amount (mass %) of lithium carbonate in the positive electrode active material layer in the positive electrode precursor, the type and amount (mass %) of the binder in the positive electrode active material layer, the type and amount (mass %) of the conductive material in the positive electrode active material layer, and the type and amount (mass %) of the dispersed material in the positive electrode active material layer. The negative electrode manufacturing conditions include the basis weight (g/m²) of the negative electrode active material layer, the thickness (μm) of the negative electrode active material layer, the bulk density (g/cc) of the negative electrode active material layer, the type and amount (mass %) of the negative electrode active material in the negative electrode active material layer, the type and amount (mass %) of the binder in the negative electrode active material layer, the type and amount (mass %) of the conductive material in the negative electrode active material layer, and the type and amount (mass %) of the dispersed material in the negative electrode active material layer.

It is preferable that the dataset A include LiB design information associated with the electrochemical feature values and material deterioration information described above. As a result, the trained model A can identify material deterioration information with even higher accuracy. Design information includes, for example, lamination form (flat type, wound type, etc.), reaction area (m²), cell thickness (mm), separator thickness (μm), separator resistance (mΩ·m²), electrolyte salt type and concentration (M), electrolyte volume (g), and excess electrolyte volume (g). “Reaction area (m²)” is the electrode area contributing to the electrode reaction and varies depending on the number of opposing electrodes and the electrode footprint. “Excess electrolyte volume (g)” is the amount of electrolyte not retained in the electrode body.

### Updating of Dataset A:

The dataset A can be updated at any time by receiving charge/discharge data for storage batteries in various deterioration states that are actually in use and have been used in the ESS to be diagnosed and controlled from the local BMS 300, and experimentally analyzing the sampled storage batteries to obtain material deterioration information.

### <Dataset B>

First, LiBs in various deterioration states the usage history of which, such as charging and discharging, is known in advance are prepared. In the acquisition of the training data, it is preferable the same type of LiB as those used in the ESS to be diagnosed and controlled, and more preferably, an LiB actually used in the ESS to be diagnosed and controlled, be used. The deterioration state may be adjusted in various manners, such as through accelerated experimentation. These LiBs are subjected to charging and discharging operations, and the charge/discharge data (current, voltage, temperature changes over time, etc.) are acquired. The charge/discharge data of the storage battery can be acquired in the same manner as the dataset A described above.

Next, the SoH is calculated based on the acquired charge/discharge data. The SoH can be calculated using conventional methods. For example, the storage battery is charged and discharged at a constant current and a constant voltage, the capacity at the current time point is measured, and the SoH is calculated as the retention rate [%] of the full charge capacity [Ah] at the time of degradation (=full charge capacity [Ah] at the time of degradation/initial full charge capacity [Ah]×100) using the initial full charge capacity [Ah] as the reference. Details are as described below in <Calculation of SoH>.

From the acquired charge/discharge data, the material deterioration information of the storage battery is then output through diagnosis processing by the trained model A, and the lithium deposition risk X is calculated based on the output material deterioration information. Details of the calculation of lithium deposition risk X are as described below in <<Calculation and Labeling Processing of Lithium Deposition Risk X>>. Charge/discharge data, SoH, and lithium deposition risk X at various measurement points (deterioration states) are measured and calculated to create the dataset B.

The dataset B preferably includes information on each component used in the LiB, associated with the charge/discharge data, SoH, and lithium deposition risk X described above. As a result, the trained model B can predict future lithium deposition risk X with even higher accuracy. The information regarding the components is the same as that used in the dataset A described above.

The dataset B preferably includes LiB design information associated with the charge/discharge data, SoH, and lithium deposition risk X described above. As a result, the trained model B can predict future lithium deposition risk X with even higher accuracy. The design information is the same as that used in the dataset A described above.

The dataset B can be updated at any time by receiving charge/discharge data for storage batteries in various deterioration states that are actually in use and have been used in the ESS to be diagnosed and controlled from the local BMS 300, and obtaining information on the SoH trends and the lithium deposition risk X trends.

### <<Diagnosis Processing>>

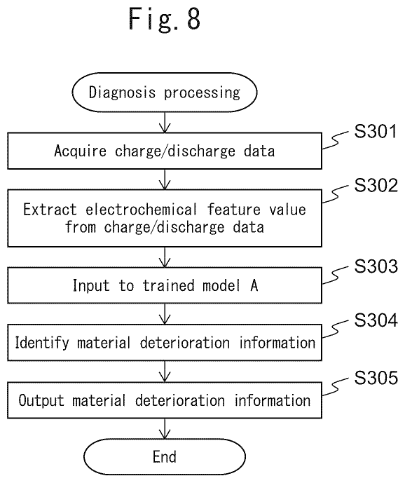

FIG. 8 is a flowchart showing an example of the operation of diagnosis processing. An example of the operation of diagnosis processing will be described below with reference to the flowchart shown in FIG. 8. Note that the flow of the operation described below is executed primarily by the diagnosis part 442 included in the processing part 440 of the cloud BMS 400 in cooperation with each element based on a program stored in advance in the storage part 430 of the cloud BMS 400.

Initially, the acquisition part (transmission/reception part 420) of the cloud BMS 400 acquires the charge/discharge data of the storage battery from the local BMS 300 (step S301). The acquisition part 420 may store the charge/discharge data in the storage part 430. The diagnosis part 442 extracts feature values (electrochemical feature values) related to the material deterioration information from the charge/discharge data (step S302). The extraction of the electrochemical feature values may be performed by calculation using the trained model A. The diagnosis part 442 inputs the charge/discharge data or inputs the electrochemical feature values extracted from the charge/discharge data into the trained model A, and diagnoses (identifies) the material deterioration information inside the storage battery, which is highly correlated with the electrochemical feature values of the charge/discharge data (steps S303 and S304). The output part (transmission/reception part 420) outputs the diagnosed (identified) material deterioration information (step S305), and the series of steps ends.

The electrochemical feature values are obtained by mathematically processing the charge/discharge data (electrochemical data), and are technically related to the material deterioration information of the storage battery. More specifically, for example, when the charge/discharge data is the voltage change over time (dOCV/dt-t plot) at the time when charging of the storage battery is stopped immediately after charging to an arbitrary SoC, the maximum value of dOCV/dt in the dOCV/dt-t plot, the presence or absence of a local maximum value (the point where d²OCV/dt²=0), and the time t (sec) at the local maximum value are extracted as electrochemical feature values. When the charge/discharge data is the voltage change over time (V-t plot) during pulse charging and/or discharging at a constant current, the overvoltage trend in the time range of 0.1 seconds to several seconds is extracted. When the change in current value over time (I-t plot) observed during constant voltage charging is used as the charge/discharge data, the presence or absence of a local minimum value (d²I/dt²=0) in the dI/dt-t plot, the current value (A) of the local minimum value, the time t (sec) at the local minimum value, and the like are extracted as electrochemical feature values. When the charge capacity and discharge capacity at a constant current or constant power are used as the charge/discharge data, the charge/discharge efficiency (Coulomb efficiency) and the like are extracted as electrochemical feature values. When measurement data obtained by AC impedance spectroscopy is used as the charge/discharge data, parameter groups such as the resistance component (Ω) and/or capacitance component (F) derived from Li metal in the Nyquist plot are extracted as electrochemical feature values. Details of the methods for extracting electrochemical feature values will be described later.

The trained model A comprehensively considers a combination of one or a plurality of the electrochemical feature values listed above and identifies one or a plurality of pieces of highly relevant material deterioration information. Material deterioration information is information related to the deterioration of components such as the positive electrode, negative electrode, separator, and electrolyte used in the storage battery. The material information includes, for example, visual, physical, and chemical information of the components. The material deterioration information preferably includes information related to the lithium deposition risk. The information related to the lithium deposition risk includes the area of deposited lithium metal analyzed from an image of the negative electrode surface of the storage battery (Li deposition area ratio (%)), the shape of the Li deposition region, the Li deposition weight (mg/m²), the distribution state and color tone of the Li deposition region, the shape of the Li metal observed by cross-sectional SEM observation of the negative electrode (Li morphology), the chemical shift value (eV) and/or the area thereof obtained from the Li(s1) spectrum obtained by XPS analysis, the chemical shift value (ppm) and/or the area thereof obtained from the ⁷Li-NMR spectrum, and information such as the chemical state expressed by the g value and/or line width obtained from the ESR spectrum. Details of the material deterioration information will be described later. More preferable examples of material deterioration information are the Li deposition area ratio (%), Li deposition weight (mg/m²), and Li morphology.

The material deterioration information is output (transmitted) from the transmission part (transmission/reception part 420) to the terminal device 500 of the user and/or the local BMS 300 via the network N. Furthermore, the diagnosed (identified) material deterioration information is used in the calculation processing of the lithium deposition risk X, which will be described below.

### <<Calculation of Deterioration State of Storage Battery>>

The calculation part 443 acquires (identifies) one or a plurality of pieces of material deterioration information from the diagnosis part through the diagnosis processing operation described above, and can calculate the deterioration state of the storage battery based on the separately calculated SoH and material deterioration information. The material deterioration information is as described above, and preferably includes information on the lithium deposition risk and information mathematically processed therefrom. Examples of calculation include weighting each of the SoH and material deterioration information in accordance with the material information of the storage battery used in the ESS and the future operation condition of the ESS, and indexing the deterioration state of the storage battery, or labeling the deterioration state of the storage battery based on one or a plurality of predetermined thresholds for each of the SoH and material deterioration information, and combinations thereof.

For example, as will be described later, the calculation part 443 labels the deterioration state of the storage battery based on one or a plurality of predetermined thresholds for the lithium deposition risk X calculated based on the SoH and the material deterioration information. The lithium deposition risk X is weighted in accordance with the material information of the storage battery used in the ESS, the future operation condition of the ESS, etc.

### <<Calculation and Labeling of Lithium Deposition Risk X>>

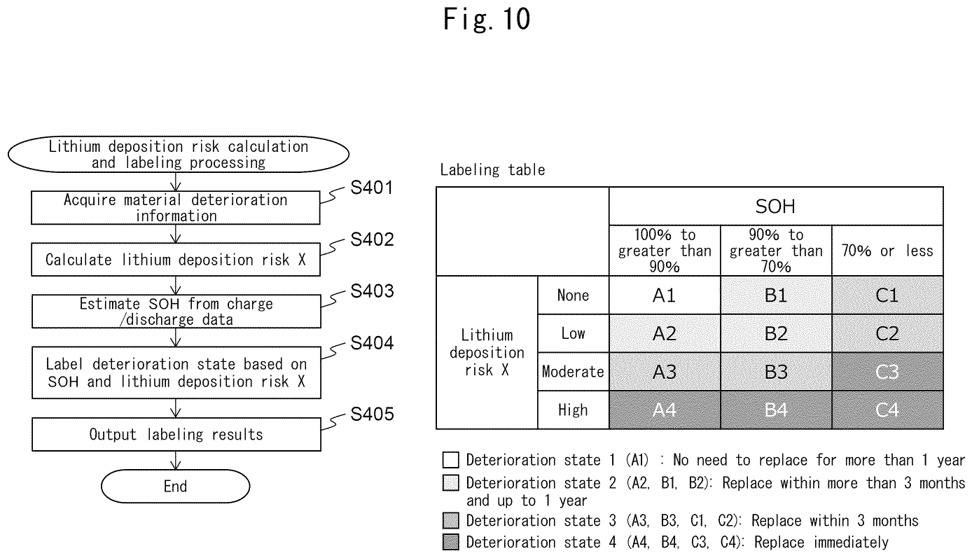

FIG. 10 is a flowchart showing an example of the operation of calculation and labeling processing of the lithium deposition risk X. The flow of the operation described below is executed primarily by the calculation part 443 included in the processing part 440 of the cloud BMS 400 in cooperation with each element based on a program stored in advance in the storage part 430 of the cloud BMS 400.

First, the calculation part 443 acquires (identifies) the material deterioration information from the diagnosis part through the diagnosis processing operation described above (step S401). Next, the calculation part 443 calculates the lithium deposition risk X based on the information including the identified material deterioration information (step S402). The lithium deposition risk X may be calculated as the sum of the lithium deposition risk X_{chem.} inferred from the material deterioration information and the lithium deposition risk X_{elec.} inferred from the charge/discharge data. Furthermore, the lithium deposition risk X_{chem.} and the lithium deposition risk X_{elec.} can be weighted in accordance with the material information of the storage battery used in the ESS and the future operation condition of the ESS. By weighting in this manner, the lithium deposition risk X can reflect differences in safety depending on the type of storage battery and the likelihood of deterioration depending on the future charge/discharge pattern of the storage battery.

In this aspect, the storage part 430 stores in advance one or a plurality of tables associating the material deterioration information of the storage battery, the lithium deposition risk X_{chem.} inferred from the material deterioration information, charge/discharge data, the lithium deposition risk X_{elec.} inferred from the charge/discharge data, the material information of the storage battery, a weighting coefficient in accordance with the material information, and the ESS operation condition and information related to the weighting coefficient in accordance with the operation condition. The calculation part 443 can refer to the table and calculate the lithium deposition risk X of the corresponding storage battery from the material deterioration information of the storage battery input from the diagnosis part. An example of a specific method for calculating the lithium deposition risk X is shown below.

<Calculation of Lithium Deposition Risk X_{chem.} Using Material Deterioration Information>

The lithium deposition risk X_{chem.} inferred from the material deterioration information can be determined by setting the lithium deposition risk X_{chem.} (n) corresponding to the material deterioration information of Item n and making a comprehensive judgment. As a method of comprehensive judgment, for example, the average value of X_{chem.} (n) can be used. Specifically, it can be determined using the following formula (1). n means the nth piece of information of the material deterioration information output from the diagnosis part, and the number of output items is 1 to nₘₐₓ.

$$\begin{matrix}[ Math 1 ] & \\ {X}_{chem .} = \frac{{\sum }_{n = 1}^{n = {n}_{max}} {X}_{chem .} ( n )}{{n}_{max}} & ( 1 )\end{matrix}$$

The storage part 430 stores a table in which the lithium deposition risk X_{chem.} (n) corresponding to various items of material deterioration information is preset, and the calculation part can refer to the table to calculate the average value of X_{chem.} (n). The setting method can be based on empirical rules, but quantification can also be achieved by building a trained model based on a database in which safety tests and ignition history of the target storage battery are associated with the material deterioration information. Table 1 below shows an example of a table in which the lithium deposition risk X_{chem.} (n) corresponding to each item of material deterioration information is set. Table 1 below is an example of the lithium deposition risk X_{chem.}, and the type and number of items to be included in the average value can be arbitrarily set.

TABLE 1

| Item | No. | Index | Risk value |
|---|---|---|---|
| Li deposition area ratio | X_{chem.} (1) | 0 to 5 | 0 to 1 |
| (%) | | | |
| Li deposition weight | X_{chem.} (2) | 0 to 100 | 0 to 1 |
| (mg/m²) | | | |
| Li shape | X_{chem.} (3) | Plate- or wire-like | 0.5 or 1 |
| XPS binding energy | X_{chem.} (4) | Presence or absence | 0 or 1 |
| (eV) | | of peak at 52 | |
| Chem shift by NMR | X_{chem.} (5) | Presence or absence | 0 or 1 |
| (ppm) | | of peak at 250 | |
| Separator black spot | X_{chem.} (6) | 0 to 5 | 0 to 1 |
| no. (spot/m²) | | | |
| . | . | . | . |
| . | . | . | . |
| . | . | . | . |

<Calculation of Lithium Deposition Risk X_{elec.} using Charge/Discharge Data>

The lithium deposition risk X_{elec.} estimated from the charge/discharge data can be determined by setting the lithium deposition risk X_{elec.} (m) corresponding to the electrochemical feature value of Item m extracted from the charge/discharge data and making a comprehensive judgment. As the method for making a comprehensive judgment, for example, the average value of X_{elec.} (m) can be used. Specifically, it can be determined using the following formula (2). m refers to the m-th information of the electrochemical feature value output from the acquisition part, and the number of output items is assumed to be 1 to mₘₐₓ.

$$\begin{matrix}[ Math 2 ] & \\ {X}_{elec .} = \frac{{\sum }_{m = 1}^{m = {m}_{max}} {X}_{elec .} ( m )}{{m}_{max}} & ( 2 )\end{matrix}$$

The storage part 430 stores a table in which the lithium deposition risk X_{elec.} (m) corresponding to various items of electrochemical feature values is preset, and the calculation part can refer to the table to calculate the average value of X_{elec.} (m). The setting method can be based on empirical rules, but quantification can also be achieved by building a trained model based on a database in which safety tests and ignition history of the target storage battery are associated with the material deterioration information. Table 2 below shows an example of a table in which the lithium deposition risk X_{elec.} (m) corresponding to each item of electrochemical feature values is set. Table 2 below is an example of the lithium deposition risk X_{elec.}, and the type and number of items to be included in the average value can be arbitrarily set.

TABLE 2

| Item | No. | Index | Risk value |
|---|---|---|---|
| Paused after | X_{elec.} (1) | tmax(s) of d²V/dt² = 0 at SoC = 10% | — |
| charging | X_{elec.} (2) | tmax(s) of d²V/dt² = 0 at SoC = 20% | — |
| | X_{elec.} (3) | tmax(s) of d²V/dt² = 0 at SoC = 30% | X = tmax/100 |
| | X_{elec.} (4) | tmax(s) of d²V/dt² = 0 at SoC = 40% | X = tmax/200 |
| | X_{elec.} (5) | tmax(s) of d²V/dt² = 0 at SoC = 50% | X = tmax/450 |
| | X_{elec.} (6) | tmax(s) of d²V/dt² = 0 at SoC = 60% | X = tmax/800 |
| | X_{elec.} (7) | tmax(s) of d²V/dt² = 0 at SoC = 70% | X = tmax/1200 |
| | X_{elec.} (8) | tmax(s) of d²V/dt² = 0 at SoC = 80% | X = tmax/1200 |
| | X_{elec.} (9) | tmax(s) of d²V/dt² = 0 at SoC = 90% | X = tmax/1200 |
| | X_{elec.} (10) | tmax(s) of d²V/dt² = 0 at SoC = 100% | X = tmax/1200 |
| Charge/discharge | X_{elec.} (11) | Discharge capacity/charge capacity A | X = {(100 − A)/ |
| efficiency | | (%) at SoC 0 to 100% | 30}³ |
| Current | X_{elec.} (12) | tmin(s) of d²I/dt² = 0 when SoC is 100% | X = tmin/1000 |
| convergence | | charged | |
| local minimum | | | |
| . | . | . | . |
| . | . | . | . |
| . | . | . | . |

### <Setting of Weighting Coefficients>

The lithium deposition risks X_{chem.} and X_{elec.} may be weighted in accordance with the type of storage battery and the future charge/discharge conditions of the ESS to calculate the overall lithium deposition risk X. For example, when considering the risk of Li metal deposition on the negative electrode surface, the lithium deposition risks X_{chem.} and X_{elec.} can be weighted by multiplying them by weighting coefficients α_{chem.} and α_{elec.}, respectively, in accordance with the information on the negative electrode of the storage battery. For example, when the weighting coefficient α_{chem.} of the material deterioration information is set to α and the weighting coefficient α_{elec.} of the electrochemical feature value is set to 1−α, then X_{chem.} based on the material deterioration information and X_{elec.} based on the electrochemical feature value can be weighted as shown in the following formula (3).

[Math 3]

X=a×X_{chem.}+(1−α)×X_{elec.} (3)

0<α<1

where α is a weighting coefficient depending on the type of negative electrode active material, and is defined as 0<α<1. α can be set in accordance with the type of negative electrode active material used in the target storage battery. For example, a peak in the dQ/dV value occurs as an electrochemical feature value of the negative electrode due to a discontinuous change in the negative electrode potential accompanying a phase transition of the negative electrode active material. When the negative electrode active material is graphite-based, this peak is easy to determine and the electrochemical feature value is easy to capture, making the electrochemical feature value more important. Conversely, when the negative electrode active material does not involve a phase transition, such as hard carbon-based materials, it is difficult to capture the electrochemical feature value, making material deterioration information more important. Thus, when the negative electrode active material is hard carbon-based, it is preferable to prioritize lithium deposition risk X_{chem.} based on material deterioration information over lithium deposition risk X_{elec.} based on electrochemical feature value information, as compared to graphite-based materials. Thus, when focusing on the negative electrode active material as the material information of the negative electrode, the weighting coefficient α of the material deterioration information can be set relatively large in the case of hard carbon-based materials.

The weighting coefficient α can be set based on experience, but it can also be quantified by building a trained model based on a database in which safety tests and ignition history of the target storage battery are associated with the material deterioration information. Table 3 below shows an example of a table in which the weighting coefficients are set in accordance with the type of the negative electrode active material.

TABLE 3

| | Plateau of negative | Plateau of negative |
|---|---|---|
| | electrode is unclear | electrode is clear |
| | (hard carbon-based | (graphite-based |
| Item | materials) | materials) |
| X_{elec.} weighting coefficient (1-α) | 0.3 | 0.5 |
| X_{chem.} weighting coefficient α | 0.7 | 0.5 |

The weighting coefficient can also be set based on information regarding the positive electrode of the storage battery, for example, the type of positive electrode active material. When the weighting coefficient based on the type of positive electrode active material is defined as β, the lithium deposition risk X can be calculated, for example, using the following formula (4):

[Math 4]

X={α×X_{chem.}+(1−α)×X_{elec.}}×β (4)

0<α<1, 0<β<1

where α is the same as in formula (3). β is a weighting coefficient depending on the type of positive electrode active material, and is defined as 0<β<1. For example, in an LiB, if a high-nickel material (such as NCM622 or NCM811) is used as the positive electrode active material, the weighting coefficient β can be set relatively large because the LiB is prone to ignition in the event of an internal short circuit. Conversely, if a lithium iron phosphate (LFP) is used as the positive electrode active material, the weighting coefficient β can be set relatively small.

The weighting coefficient β can be set based on experience, but it can also be quantified by building a trained model based on a database in which safety tests and ignition history of the target storage battery are associated with the material deterioration information. Table 4 below shows an example of a table in which the weighting coefficients are set in accordance with the type of the positive electrode active material.

TABLE 4

| Item | NCM811 | NCM622 | NCM523 | NCM111 | LFP |
|---|---|---|---|---|---|
| Weighting | 1 | 0.9 | 0.8 | 0.8 | 0.6 |
| coefficient β | | | | | |

The lithium deposition risk may be weighted by a weighting coefficient depending on the operation condition of the ESS. Examples of the operation condition of the ESS include the C rate of charge and discharge, the number of charge and discharge cycles performed in one day, and the battery temperature. When the weighting coefficient according to the operation condition of the ESS is defined as γ, the weighting coefficient corresponding to the C rate of charge and discharge is defined as γₜᵢₘₑ, the weighting coefficient corresponding to the number of charge and discharge cycles performed in one day is defined as γ_{cycle}, and the weighting coefficient corresponding to the battery temperature is defined as γ_{temp.}, the lithium deposition risk X can be calculated, for example, by the following formula (5):

[Math 5]

X=α×X_{chem.}+(1−α)×X_{elec.})×β×γ (5)

γ=γₜᵢₘₑ×γ_{cycle}×γ_{temp.}

0<α<1, 0<β<1, 0<γₜᵢₘₑ<1, 0<γ_{cycle}<1, 0<<γ_{temp.}<1

where α and β are the same as in formulas (3) and (4) above. γₜᵢₘₑ is a weighting coefficient corresponding to the charge/discharge C rate, γ_{cycle} is a weighting coefficient corresponding to the number of charge/discharge cycles performed in one day, and γ_{temp.}. is a weighting coefficient corresponding to the battery temperature, with 0<γₜᵢₘₑ<1, 0<γ_{cycle}<1, and 0<γ_{temp.}<1. A high charge/discharge C rate poses a risk of causing more severe degradation of the LiB. For example, during charging, at a high C rate, the insertion reaction of Li ions into the negative electrode active material cannot keep up, resulting in the risk of Li metal precipitation on the negative electrode surface. Thus, the higher the charge/discharge C rate, the larger the γₜᵢₘₑ can be set. Furthermore, a large number of charge/discharge cycles per day provides the LiB with more charge/discharge history, making it more susceptible to degradation. Thus, the greater the number of charge/discharge cycles per day, the larger the γ_{cycle} can be set. When the battery temperature is excessively low, the insertion reaction of Li ions into the negative electrode during charging of the LiB becomes difficult, which makes Li metal more likely to precipitate. Conversely, when the battery temperature is excessively high, high resistance occurs due to the acceleration of SEI formation in the negative electrode active material, which inhibits the insertion reaction of Li ions, making Li metal more likely to precipitate. Thus, since the risk of Li metal precipitation increases as the battery temperature becomes higher or lower relative to room temperature, γ_{temp.}. can be set relatively large.

The weighting coefficients γₜᵢₘₑ, γ_{cycle}, and γ_{temp.} can be set based on empirical rules, but can also be quantified by building a trained model based on a database in which safety tests and ignition history of the target storage battery are associated with material deterioration information. Tables 5 to 7 below show examples of tables in which the weighting coefficients are set in accordance with the type of the positive electrode active material.

TABLE 5

| Time ratio(hr) | γₜᵢₘₑ |
|---|---|
| 0.5 | 1.00 |
| 1 | 0.60 |
| 2 | 0.40 |
| 4 | 0.30 |
| 8 | 0.25 |

TABLE 6

| Cycle number/day | γ_{cycle} |
|---|---|
| 1 | 0.5 |
| 2 | 0.7 |
| 3 | 0.9 |
| 4 | 1 |

TABLE 7

| Temp (°C) | γ_{temp.} |
|---|---|
| −20 °C | 1 |
| 0 °C | 0.8 |
| 10 °C | 0.7 |
| 25 °C | 0.6 |
| 30 °C | 0.6 |
| 40 °C | 0.7 |
| 50 °C | 0.8 |

As described above, the lithium deposition risk X can be comprehensively calculated by weighting the weighting coefficients α_{chem.} and α_{elec.} estimated from the material deterioration information and electrochemical feature values according to the material information of the storage battery and the operation condition of the ESS, etc. However, as long as an appropriate coefficient item can be set in accordance with the type of storage battery, the operation condition of the ESS, etc., the method for calculating the lithium deposition risk X is not limited to the specific examples described above.

### <Estimation of Lithium Deposition Risk X Using Results of Safety Tests on Storage Batteries>

As an example of setting the lithium deposition risk X, estimation using a trained model C, which has learned material deterioration information and the results of safety tests on the target storage battery, will be described below.

Safety tests are tests for verifying whether a dangerous event such as heat generation, unsealing, gas emission, or ignition occurs when a storage battery is subjected to heat or external stress. Examples of safety tests for storage batteries include various methods such as overcharge tests, overdischarge tests, heating tests, nail penetration tests, crush tests, differential pressure tests, drop tests, external short circuit tests, and internal short circuit tests. Standards for safety test methods are established, such as JIS C8715-2 “Secondary lithium cells and batteries for use in industrial applications—Part 2: Safety requirements,” IEC 62660-3 “Lithium-ion Secondary Batteries for Electric Vehicle Propulsion—Safety Requirements,” and ISO 12405-1 “Electric Vehicles—Test Specification for Lithium-ion Battery Pack Systems—Part 3: Safety Requirements.” Since the risk of such an event occurring in a dangerous manner is high when the materials constituting the storage battery are in a certain deterioration state, associating the deterioration state of the materials with the results of safety tests will provide important insight into understanding the dangers posed by the ESS storage battery when it is in a certain deterioration state.

As an example of material deterioration information, the precipitation of Li metal will be described. Precipitated Li metal is generally active, and when exposed to high temperatures, reacts with the electrolyte, causing localized heat generation near the deposited Li metal. Localized heat generation within a storage battery can cause the positive electrode active material in the vicinity to undergo thermal decomposition, leading to thermal runaway and potential ignition. By understanding the amount, form, and chemical state of the precipitated Li metal, as well as events such as heat generation and ignition which occur during heating tests, the risk of ignition in storage batteries operated in ESSs can be predicted.

The material deterioration information learned by the trained model C for estimating lithium deposition risk X may be the same as the material deterioration information learned by the trained model A for diagnosing the material deterioration information described above. Specifically, information related to the deposition of Li metal on the negative electrode, which is directly related to the safety of the LiB, is preferable, and examples thereof include the deposition area, the shape of the deposition region, the deposition weight, the distribution state, and the color tone of deposited lithium metal analyzed from an image of the negative electrode surface of the storage battery, the shape of lithium metal observed by cross-sectional SEM observation of the negative electrode, the chemical shift value (eV) and/or the area thereof obtained from the Li(s1) spectrum obtained by XPS analysis, the chemical shift value (ppm) and/or the area thereof obtained from the ⁷Li-NMR spectrum, and the chemical state expressed by the g value and/or line width obtained from the ESR spectrum.

As the results of safety tests learned by the trained model C for estimating the lithium deposition risk X, when the purpose of learning is to focus on lithium metal deposition, the results of tests such as overcharge tests, heating tests, nail penetration tests, crush tests, drop tests, external short circuit tests, and internal short circuit tests, expressed as values in terms of hazard levels (for example, hazard levels defined by the EUCAR Hazard Levels), and storage battery data such as temperature, current, and voltage obtained at the time of an event can be used.

The method for creating a trained model C for estimating lithium deposition risk X comprises creating a database of material deterioration information obtained by disassembling and analyzing a storage battery in a given deterioration state, prepared for acquiring training data, and information obtained from the results of safety tests on storage batteries in a similar deterioration state; and using these as training data to train a machine learning model and learn the correlation between at least one piece of material deterioration information and the information from the safety test results. Since it is preferable to collect information on various deterioration states for a single storage battery type when preparing storage batteries for acquiring training data, it is preferable to prepare a large number of storage batteries in various deterioration states by conducting accelerated tests such as cycle tests, high-temperature storage tests, and float tests. Furthermore, by using the results of analysis of the constituent materials of LiBs obtained by acquiring and disassembling LiBs actually used in ESS operation, the lithium deposition risk X can be estimated with even greater accuracy.

### <Calculation of SoH>

The calculation part 443 of the cloud BMS 400 calculates (estimates) the state of health (SoH) of the storage battery based on the acquired charge/discharge data (step S403). The SoH is generally expressed as the retention rate [%] of the full charge capacity [Ah] at the time of degradation, based on the initial full charge capacity [Ah](=full charge capacity [Ah] at the time of degradation/initial full charge capacity [Ah]×100), or as the increase rate [%] of the internal resistance [Ω] at the time of degradation, based on the initial internal resistance [Ω] (=internal resistance [Ω] at the time of degradation/initial internal resistance [Ω]×100), and either calculation standard may be used. The SoH may be calculated by the calculation part 342 of the local BMS 300. The SoH can be estimated by conventional methods, such as (1) estimation based on the capacity when the storage battery is charged and discharged at a constant current and a constant voltage, (2) estimation based on the internal resistance obtained by the AC impedance method, (3) estimation based on the internal resistance obtained from the slope of the current-voltage characteristics (IV characteristics), (4) estimation based on the internal resistance obtained from the voltage transient response when the current is changed in steps, (5) estimation by fitting the charging curve data using a regression equation or a model, or (6) estimation based on an equivalent circuit or physical model which behaves similarly to the charge/discharge data of the storage battery, or a combination of these.

(1) More specifically, in estimation based on the capacity when a storage battery is charged and discharged at a constant current and a constant voltage, the storage battery is first charged and discharged at a constant current and a constant voltage, and the capacity at the current time point is measured. The initial full charge capacity [Ah] is then used as a reference, and the maintenance rate [%] of the full charge capacity [Ah] at the time of degradation (=full charge capacity [Ah] at the time of degradation [Ah]/initial full charge capacity [Ah]×100) is calculated as the SoH.

Depending on the specifications of the storage battery, it may be possible to evaluate the SoH by accumulating charge/discharge history.

(2) Estimation based on internal resistance obtained by the AC impedance method involves applying a single or multiple frequency AC current to a storage battery using a dedicated measuring device to measure the impedance at each frequency. The frequency characteristics of the internal resistance of the storage battery are acquired (electrochemical impedance spectroscopy) and fitted to an equivalent circuit (determining the circuit constants), whereby the internal resistance can be separated. Using the initial internal resistance (Ω) as the reference, the increase rate (%) of internal resistance (Ω) during degradation (=internal resistance (Ω) during degradation (Ω)/initial internal resistance (Ω)×100) is then calculated as the SoH.

(3) Estimation based on the internal resistance obtained from the slope of the current-voltage characteristic (IV characteristic) is performed by creating a current-voltage characteristic (IV characteristic) for each SoH from the charge/discharge curve (rate characteristic) of the storage battery. The IV characteristic is linearly approximated, and the internal resistance is calculated from the slope. Using the initial internal resistance [Ω] as the reference, the rate of increase [%] of the internal resistance [Ω] during degradation (=internal resistance [Ω] during degradation [Ω]/initial internal resistance [Ω]×100) is then calculated as the SoH. Because the IV characteristic cannot always be linearly approximated, it is preferable to make corrections based on the temperature and current value of the storage battery to ensure estimation accuracy.

(4) In estimation based on internal resistance obtained from the voltage transient response when the current is changed stepwise, a specific current pattern that changes stepwise is applied to the storage battery and the voltage response is measured. The internal resistance can be calculated by dividing the voltage drop [V] from the open circuit voltage by the current value [A]. Using the initial internal resistance [Ω] as the reference, the increase rate [%] of the internal resistance [Ω] during degradation (=internal resistance [Ω] during degradation [Ω]/initial internal resistance [Ω]×100) is then calculated as the SoH.

(5) Estimation by fitting charging curve data using a regression equation or model is a method of estimating the degree of deterioration and actual capacity from the profile of the charging and discharging curve. The charging and discharging curve data can be fitted (circuit constants are determined) using a regression equation or equivalent circuit to estimate the internal resistance. The SoH is then calculated as the percentage increase in internal resistance (Ω) during deterioration (=internal resistance (Ω) during deterioration/initial internal resistance (Ω)×100) based on the initial internal resistance (Ω).

(6) Estimation based on an equivalent circuit or physical model which behaves similarly to the charge/discharge data of a storage battery is a method for estimating SOH by expressing a virtual storage battery (model) using an equivalent circuit or equations based on physical phenomena. Model construction and parameter determination are required for each storage battery specification. Model construction includes modeling phenomena within the storage battery, such as electrochemical reactions, Li transport (migration, diffusion) within the electrolyte, Li transport (diffusion) within the active material, and degradation reactions (increase in internal resistance, electrolyte decomposition). The internal resistance of the constructed virtual storage battery is defined as the internal resistance at the time of degradation [Ω], and the increase rate [%] from the initial internal resistance [Ω](=internal resistance at the time of degradation [Ω]/initial internal resistance [Ω]×100) is then calculated as the SOH.

Among these, because of their excellent accuracy in estimating the SoH, it is preferable to calculate (estimate) the SoH by (1) estimating based on the capacity when the storage battery is charged and discharged at a constant current and a constant voltage, or (3) estimating based on the internal resistance obtained from the slope of the current-voltage characteristics (IV characteristics).

### <Labeling Processing>

The calculation part 443 of the cloud BMS 400 labels the deterioration state of the storage battery based on one or a plurality of predetermined thresholds for the calculated SoH and the lithium deposition risk X (step S404). The output part (transmission/reception part 420) then outputs the labeling results (step S405), and the series of steps ends. Labeling can be performed based on a labeling table stored in advance in the storage part 430. As illustrated in the labeling table of FIG. 10, the SoH, expressed as the capacity maintenance rate, may be divided into three levels: 70% or less, greater than 70% and up to 90%, and greater than 90% and up to 100%. Furthermore, the lithium deposition risk X may be divided into four levels: “none” (less than 0.1), “low” (0.1 to less than 5.0), “medium” (5.0 to less than 10.0), and “high” (10.0 or greater). As exemplified by the labeling table of FIG. 10, the deterioration state of the storage battery is classified into 12 different quadrants, A1 to A4, B1 to B4, and C1 to C4, and the deterioration state of the storage battery is labeled as indicated below. The labeling results correspond to the predicted replacement time of the storage battery if operation continues under the ESS operation condition at the current time point.
Deterioration state 1 (A1): No need to replace for more than one year
Deterioration state 2 (A2, B1, B2): Replace within more than three months and up to one year
Deterioration state 3 (A3, B3, C1, C2): Replace within three months
Deterioration state 4 (A4, B4, C3, C4): Replace immediately

The labeling processing of FIG. 10 is merely exemplary, and the number and values of thresholds, the number of labelings and the quadrant classification method, and the replacement timing corresponding to the labeling can be arbitrarily set in accordance with the operation condition of the ESS, the material information of the storage battery, design information, calculation results of the future lithium deposition risk X, which will be described later, etc. The labeling table can be set based on empirical rules, but it may also be constructed based on a database in which the material information, design information, deterioration state, charge/discharge conditions, and the period until replacement of the target storage battery are associated with each other.

The labeling results are output (transmitted) from the transmission part (transmission/reception part 420) to the terminal device 500 of the user via the network N. The labeling results may also be output (transmitted) to the EMS 240 and/or the local BMS 300. The labeling results are also used for control processing of the storage battery, which will be described below.

### <<Calculation and Labeling of Future Lithium Deposition Risk X>>

### <Calculation of Future Lithium Deposition Risk X>

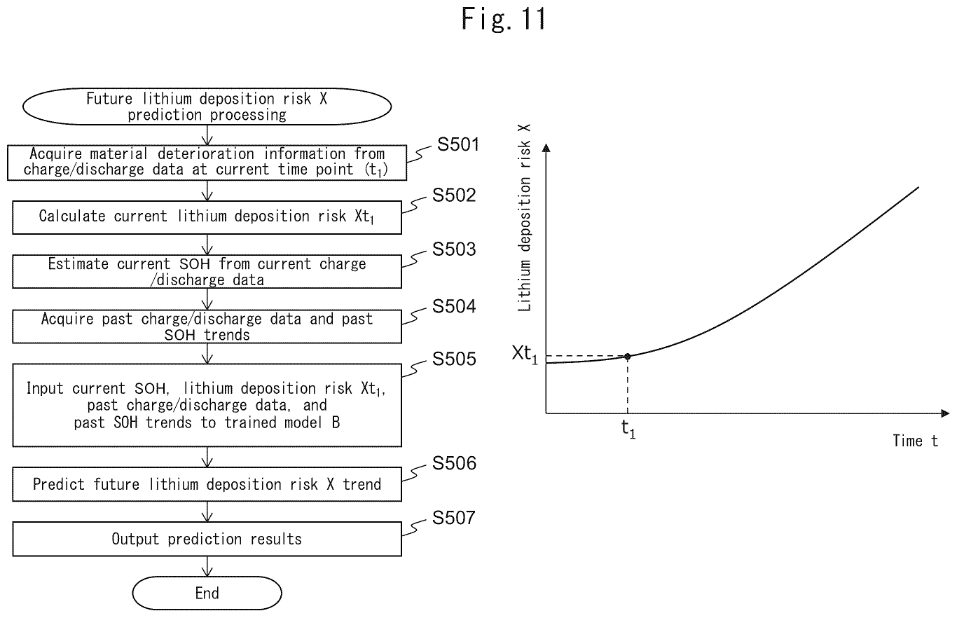

FIG. 11 is a flowchart showing an example of operations for predicting the future lithium deposition risk X. The operation flow described below is executed primarily by a calculation part 443 and a prediction part 444 included in the processing part 440 of the cloud BMS 400 in cooperation with each element based on a program stored in advance in the storage part 430 of the cloud BMS 400.

First, the calculation part 443 acquires (identifies) the material deterioration information based on the charge/discharge data at the current time point (t₁), which is estimated and calculated from the charge/discharge data at the current time point (t₁) by the diagnosis processing operation described above (step S501). Next, the calculation part 443 calculates the lithium deposition risk Xt₁ at the current time point (t₁) based on the information including the identified material deterioration information at the current time point (t₁) (step S502). The calculation part 443 then calculates (estimates) the SoH at the current time point (t₁) based on the charge/discharge data at the current time point (t₁) (step S503). These steps S501 to S503 are substantially the same as steps S401 to S403 of FIG. 10 described above, though the charge/discharge data used is specified as that of the current time point (t₁).

Next, the prediction part 444 acquires information including past charge/discharge data and past SoH trends (step S504). The information including past charge/discharge data and past SoH trends can be acquired from the integrated database stored in the storage part 430 of the cloud BMS 400, or may be acquired from the database stored in the storage part 330 of the local BMS 300. The information may include past ESS operation conditions in addition to past charge/discharge data and past SoH. The prediction part 444 then inputs the information including the SoH at the current time point, the lithium deposition risk Xt₁ at the current time point, and the past charge/discharge data and past SoH trends into the trained model B, and predicts the future lithium deposition risk X trend, which is highly correlated with this information (steps S505 to S506). The output part (transmission/reception part 420) then outputs the prediction result (step S507), and the series of steps ends. As illustrated in the graph of FIG. 10, the future lithium deposition risk X trend is represented as a curve on the right side of the current time point (t₁).

The prediction result is output (transmitted) from the transmission part (transmission/reception part 420) to the terminal device 500 of the user via the network N. The prediction result may also be output (transmitted) to the EMS 240 and/or the local BMS 300. The prediction result is also used for control processing of the storage battery, which will be described later.

### <Labeling Processing Based on Future Lithium Deposition Risk X>

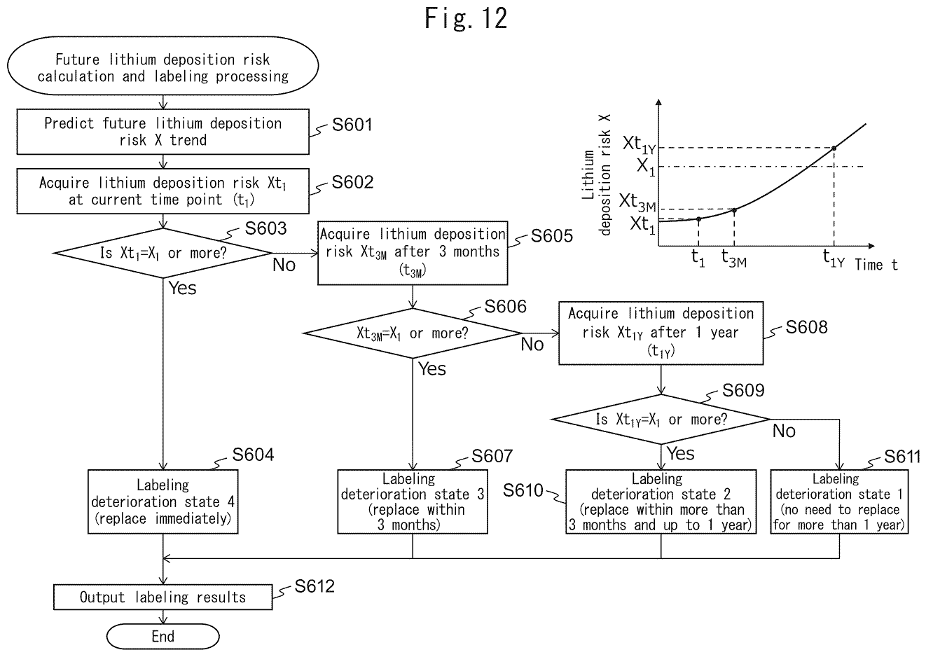

FIG. 12 is a flowchart showing an example of processing for labeling the deterioration state of a storage battery based on the future lithium deposition risk X. The operation flow described below is executed primarily by the calculation part 443 and the prediction part 444 included in the processing part 440 of the cloud BMS 400 in cooperation with each element based on a program stored in advance in the storage part 430 of the cloud BMS 400.

First, the prediction part 444 predicts the future lithium deposition risk X trend by the prediction processing operation described above (step S601). Next, the calculation part 443 calculates the lithium deposition risk Xt₂ at a certain time point (t₂) in the future based on the predicted future lithium deposition risk X trend, and then labels the deterioration state of the storage battery based on one or a plurality of predetermined thresholds for the lithium deposition risk Xt₂.

More specifically, the calculation part 443 first acquires the lithium deposition risk Xt₁ at the current time point and determines whether Xt₁ is equal to or greater than a preset threshold X₁ (steps S602 to S603). When Xt₁ is equal to or greater than X₁ (Yes), the calculation part 443 labels the storage battery as deterioration state 4 (replace immediately) (step S604). When Xt₁ is less than X₁ (No), the calculation part 443 next acquires the lithium deposition risk Xt_{3M} three months later (t_{3M}) from the future lithium deposition risk X trend and determines whether Xt_{3M} is equal to or greater than X₁ (steps S605 to S606). When Xt_{3M} is greater than or equal to X₁ (Yes), the calculation part 443 labels the storage battery as deterioration state 3 (replace within three months) (step S607). When Xt_{3M} is less than X₁ (No), the calculation part 443 next acquires the lithium deposition risk Xt_{1Y} one year later (t_{1Y}) from the future lithium deposition risk X trend, and determines whether Xt_{1Y} is greater than or equal to X₁ (steps S608 to S609). When Xt_{1Y} is greater than or equal to X₁ (Yes), the calculation part 443 labels the storage battery as deterioration state 2 (replace within more than three months and up to one year) (step S610). When Xt_{1Y} is less than X₁ (No), the calculation part 443 labels the storage battery as deterioration state 1 (no need to replace for more than one year) (step S611). The output part (transmission/reception part 420) then outputs the labeling results (step S612), and the series of steps ends.

FIG. 12 visually represents the relationship between the future lithium deposition risk X trend used in this labeling process and Xt₁, Xt_{3M}, Xt_{1Y}, and X₁. In this example, since Xt_{3M} is less than X₁ (No), but Xt_{1Y} is equal to or greater than X₁ (Yes), the calculation part 443 labels the storage battery as deterioration state 2 (replace within more than three months and up to one year).

The labeling processing of FIG. 12 is merely exemplary, and the number and values of the thresholds can be arbitrarily set in accordance with the operation condition of the ESS, the material information of the storage battery, design information, etc. For example, as illustrated in the labeling table in FIG. 10, threshold X₁ is a level at which it is determined that the lithium deposition risk is “medium” to “high” and that battery replacement is necessary. The number of labels, the classification method, and the replacement timing corresponding to the labeling can be arbitrarily set in accordance with the type of storage battery, etc. The labeling table can be set based on empirical rules, but it can also be constructed based on a database in which the material information, design information, deterioration state, charge/discharge conditions, and the period until replacement of the target storage battery, etc., are associated with each other.

The labeling results are output (transmitted) from the transmission part (transmission/reception part 420) to the terminal device 500 of the user via the network N. The labeling results may also be output (transmitted) to the EMS 240 and/or the local BMS 300. The labeling results are also used for control processing of the storage battery, which will be described later.

### <<Control Processing>>

### <Control Processing Aspect 1: Control Based on Lithium Deposition Risk X>

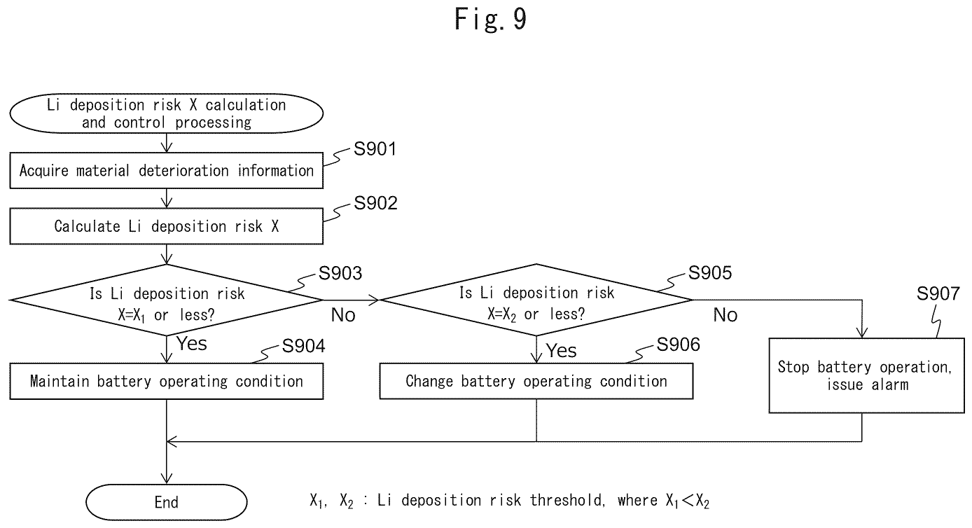

An example of the operation of control processing based on the lithium deposition risk X will be described with reference to FIG. 9. The operation flow described below is executed primarily by the control part 445 included in the processing part 440 of the cloud BMS 400 in cooperation with each element based on a program stored in advance in the storage part 430 of the cloud BMS 400.

The processing part 440 further comprises a control part 445 for controlling the charging and discharging conditions of the storage battery based on the lithium deposition risk X described above. The control part 445 controls the ESS by transmitting a charge/discharge condition change command or a charge/discharge stop command to the power converter 100 or the end BMS 230 based on the lithium deposition risk X. Transmitting includes transmitting from the cloud BMS 400 to the power converter 100 or the end BMS 230 via a wired or wireless connection, and transmitting via the network N. The output lithium deposition risk X, in the same manner as the material deterioration information, is transmitted to the terminal device 500 of the user via the network N. Furthermore, an alert can be issued to the terminal device 500 of the user via the network N in accordance with the lithium deposition risk X. The alert may also be issued to the local BMS 300.

First, the diagnosis part acquires (identifies) the material deterioration information through the diagnosis processing operation described above (step S901). Next, the calculation part calculates the lithium deposition risk X based on the information including the identified material deterioration information (step S902).

Based on the lithium deposition risk X calculated in the calculation of lithium deposition risk X (step S902), the control part compares the lithium deposition risk X with a preset threshold of lithium deposition risk X. In the example of FIG. 9, two thresholds, X₁ and X₂ (where X₁<X₂), are set as the ignition risk threshold.

The control part first compares the lithium deposition risk X with the threshold X₁ and determines whether the lithium deposition risk X is equal to or less than X₁ (step S903). When the lithium deposition risk X is equal to or less than X₁, the control part maintains the operation condition as planned (step S904), and the series of steps ends.

When the lithium deposition risk X exceeds X₁, the control part then compares the lithium deposition risk X with the threshold X₂ to determine whether the lithium deposition risk X is equal to or less than X₂ (step S905). When the lithium deposition risk X exceeds X₁ and is equal to or less than X₂, it is determined that degradation has progressed to a certain extent, and a command to change (relax) the operation condition of the storage battery to reduce the risk of ignition is output to the power converter 100 (step S906), and the series of steps ends. Any method for relaxing the operation condition may be used as long as it can suppress degradation of the storage battery, and examples of such methods include narrowing the operating voltage range, reducing the maximum power, reducing the C rate during charging at a high SoC %, reducing the charging SoC %, and optimizing the operating temperature.

When the lithium deposition risk X exceeds X₂, the degree of deterioration of the storage battery is deemed to be unacceptable from a safety standpoint, and the control part outputs a command to the end BMS 230 to stop operation of the corresponding storage battery, and also issues an alert from the transmission part (transmission/reception part 420) to the terminal device 500 of the user via the network N (step S907), and the series of steps ends.

By controlling the storage battery in accordance with the lithium deposition risk X as described above, the ESS can be operated more safely. Though the case in which the threshold is set to two levels has been described in the example of FIG. 9, the threshold can be set to any number of levels so that the ESS can be controlled or stopped more safely.

### <Control Processing Aspect 2: Control Based on Labeling Results>

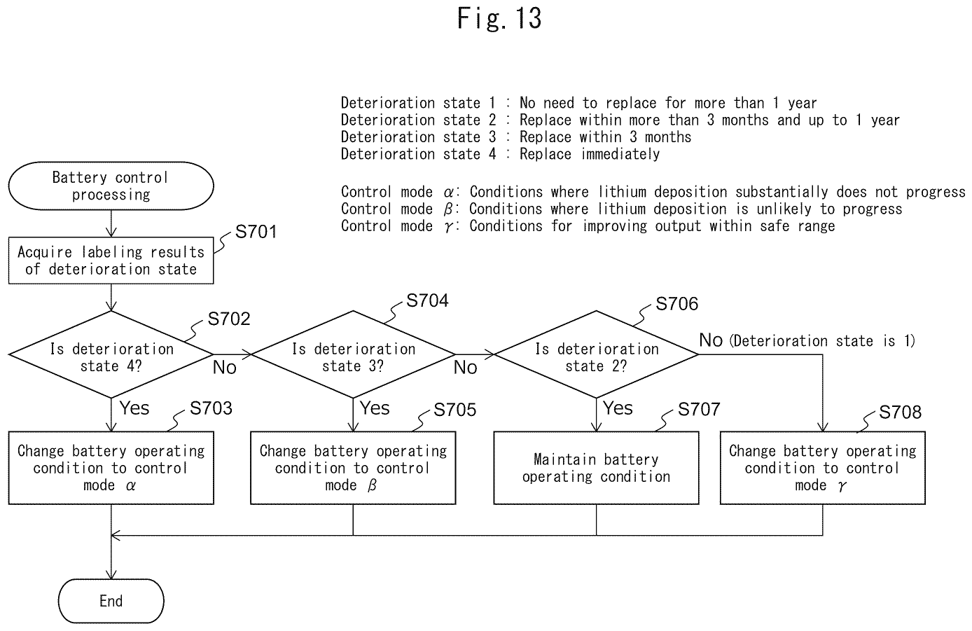

FIG. 13 is a flowchart showing an example of the operations of control processing of the storage battery based on the labeling results. Note that the operation flow described below is executed primarily by the control part 445 included in the processing part 440 of the cloud BMS 400 in cooperation with each element based on a program stored in advance in the storage part 430 of the cloud BMS 400.

First, the control part 445 acquires the labeling results described above and determines whether the storage battery is in deterioration state 4 (replace immediately) (steps S701 and S702). When the storage battery is in deterioration state 4 (Yes), the control part 445 changes the charge/discharge conditions of the storage battery to control mode a (step S703), and the series of steps ends. When the storage battery is not in deterioration state 4 (No), the control part 445 determines whether the storage battery is in deterioration state 3 (replace within three months) (step S704). When the storage battery is in deterioration state 3 (Yes), the control part 445 changes the charge/discharge conditions of the storage battery to control mode R (step S705), and the series of steps ends. When the storage battery is not in deterioration state 3 (No), the control part 445 determines whether the storage battery is in deterioration state 2 (replace within greater than three months and up to one year) (step S706). When the storage battery is in deterioration state 2 (Yes), the control part 445 maintains the charge/discharge conditions of the storage battery (step S707), and the series of steps ends. When the storage battery is not in deterioration state 2 (No), and specifically, when the storage battery is in deterioration state 1 (no need to replace for more than one year), the control part 445 changes the charge/discharge conditions of the storage battery to control mode γ (step S708), and the series of steps ends. The control modes α to γ as referenced herein respectively correspond to the following conditions:
Control mode α: Conditions under which lithium deposition substantially does not progress
Control mode β: Conditions under which lithium deposition is unlikely to progress
Control mode γ: Conditions for improving output within a safe range

Control modes α and β may be any method capable of suppressing lithium deposition. Examples include narrowing the voltage range during use, reducing the maximum power during use, reducing the C rate during charge and discharge, reducing the charge State of Charge (SoC) (%), and optimizing the operating temperature, and these methods may also be combined. Among these, reducing the C rate during charging and discharging and reducing the voltage during use (reducing the upper limit voltage) are effective for suppressing lithium deposition. For example, in control mode a, the C rate is reduced to 25% to 50% and the upper limit voltage is reduced to 60% to 80% based on the C rate and upper limit voltage before the control (100%). In control mode β, the C rate is reduced to 50% to 75% and the upper limit voltage is reduced to 80% to 90% based on the C rate and upper limit voltage before the control. Control mode y may be any method capable of improving the output of the storage battery within a safe range. Examples include widening the voltage range during use, increasing the maximum power during use, increasing the C rate during charging and discharging, increasing the charge SoC (%), and optimizing the operating temperature, and these methods may be combined. For example, in control mode y, the C rate and upper limit voltage before control are set as the reference (100%), and the C rate is increased to 101% to 120% and the upper limit voltage is increased to 101% to 120%. The control modes described above are merely exemplary, and specific conditions can be arbitrarily set in accordance with the material information and design information of the storage battery. The control mode can be set based on empirical rules, or it can be set based on a database in which the deterioration state of the target storage battery, charge and discharge conditions, and the period until replacement are associated with each other.

The control mode can be further modified based on factors contributing to storage battery degradation. As described above, the material deterioration information of the storage battery obtained by the trained model A includes information on the deterioration of materials inside the storage battery (such as the positive electrode, negative electrode, electrolyte, and separator). Thus, by identifying the materials (components) contributing to storage battery degradation, the control mode can be further optimized to suppress the deterioration of those materials (components). When deterioration of the negative electrode, for example, a decrease in the amount of lithium in the negative electrode, is the cause of the deterioration, avoiding the use of a range near the lower limit of the SoC (%) is effective to prevent negative electrode deterioration due to uneven intercalation reactions caused by charging and discharging in the low SoC (%) range. Furthermore, if deterioration of the positive electrode, for example, destruction of the positive electrode active material, is the cause of the deterioration, avoiding the use of a range near the upper limit of the SoC (%) is effective to suppress positive electrode interface deterioration due to the oxidative decomposition reaction of the electrolyte that occurs at the interface between the positive electrode and the electrolyte when high voltage is applied.

In a preferable aspect, the storage battery is composed of a plurality of storage battery modules 210 arranged in series and/or parallel, each comprising a plurality of cells arranged in series and/or parallel. The diagnosis part 442 and the calculation part 443 diagnose and label the deterioration state of each storage battery module, and the control part 445 controls the charge and discharge conditions for each storage battery module. As described above, the plurality of storage batteries constituting one storage battery module are typically connected in series, and the plurality of storage battery modules are connected in parallel. Thus, from a safety standpoint, when replacing batteries, each storage battery module, which is composed of a plurality of storage batteries connected in series, is shut down and replaced. Thus, diagnosing, labeling, and controlling each storage battery module is rational and efficient in terms of actual ESS operation.

### <Control Based on Diagnosis Results and Target Operation Period>

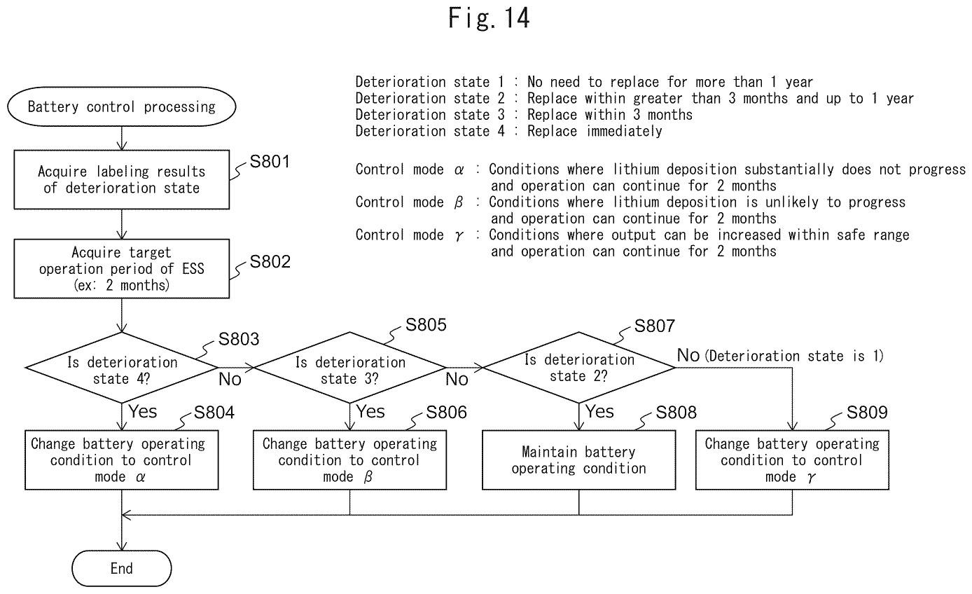

FIG. 14 is a flowchart showing an example of the operation of control processing of the storage battery based on the diagnosis results and the target operation period. Note that the operation flow described below is executed primarily by the control part 445 included in the processing part 440 of the cloud BMS 400 in cooperation with each element based on a program stored in advance in the storage part 430 of the cloud BMS 400.

First, the control part 445 acquires the results of the labeling described above (step S801). Next, the control part 445 acquires information regarding the target operation period of the ESS (step S802). The target operation period of the ESS can be arbitrarily determined based on various factors. For example, if the ESS is used to operate equipment in a factory, the target operation period may be set to the time of scheduled maintenance of the equipment (for example, in two months). Alternatively, the target operation period may be set to the time when batteries with the desired performance and quantity can be procured (for example, in two months) based on the market conditions of new storage batteries or reused batteries to be replaced. Furthermore, based on prediction information of the electricity market price, the target operation period can be determined to minimize opportunity losses, for example, by aligning the ESS maintenance period with a period when the electricity market price is expected to rise by equal to or greater than a predetermined amount.

Next, the control part 445 determines whether the storage battery is in deterioration state 4 (replace immediately) (step S803). When the storage battery is in deterioration state 4 (Yes), the control part 445 changes the charge/discharge conditions of the storage battery to control mode a (step S804), and the series of steps ends. When the storage battery is not in deterioration state 4 (No), the control part 445 determines whether the storage battery is in deterioration state 3 (replace within three months) (step S805). When the storage battery is in deterioration state 3 (Yes), the control part 445 changes the charge/discharge conditions of the storage battery to control mode R (step S806), and the series of steps ends. When the storage battery is not in deterioration state 3 (No), the control part 445 determines whether the storage battery is in deterioration state 2 (replace within greater than three months and up to one year) (step S807). When the storage battery is in deterioration state 2 (Yes), the control part 445 maintains the charge/discharge conditions of the storage battery (step S808), and the series of steps ends. When the storage battery is not in deterioration state 2 (No), and specifically, when the storage battery is in deterioration state 1 (no need to replace for more than one year), the control part 445 changes the charge/discharge conditions of the storage battery to control mode γ (step S809), and the series of steps ends. The control modes α to γ referenced herein respectively correspond to the following conditions:
Control mode α: Conditions under which lithium deposition substantially does not progress and operation can be continued for two months
Control mode β: Conditions under which lithium deposition is unlikely to progress and operation can be continued for two months
Control mode γ: Conditions under which output can be increased within a safe range and operation can be continued for two months

Control modes α to γ can be set in the same manner as described above in “Control Based on Diagnosis Results,” except that the target operation period is taken into consideration. The control modes can also be modified in the same manner depending on the cause of storage battery degradation. It is also preferable to diagnose, label, and control each storage battery module.

### MODIFICATION EXAMPLES

Above, an aspect in which the cloud BMS 400 performs all of diagnosis processing, calculation and prediction processing of current and future lithium deposition risk X, labeling processing, and control processing of Aspects 1 and 2 was primarily described as an example of an embodiment.

In this aspect, reducing the functions of the local BMS 300 is expected to reduce the equipment costs of the ESS. However, in the diagnosis system 1, any device constituting the system may function as the diagnosis device as long as the diagnosis and other functions of the present disclosure can be implemented as an entire system connected to each other via a network.

Furthermore, the diagnosis device (diagnosis part), calculation device (calculation part), and controller (control part) may be configured as a single device or may be configured as a plurality of devices connected to each other via the network N.

### Modification Example 1

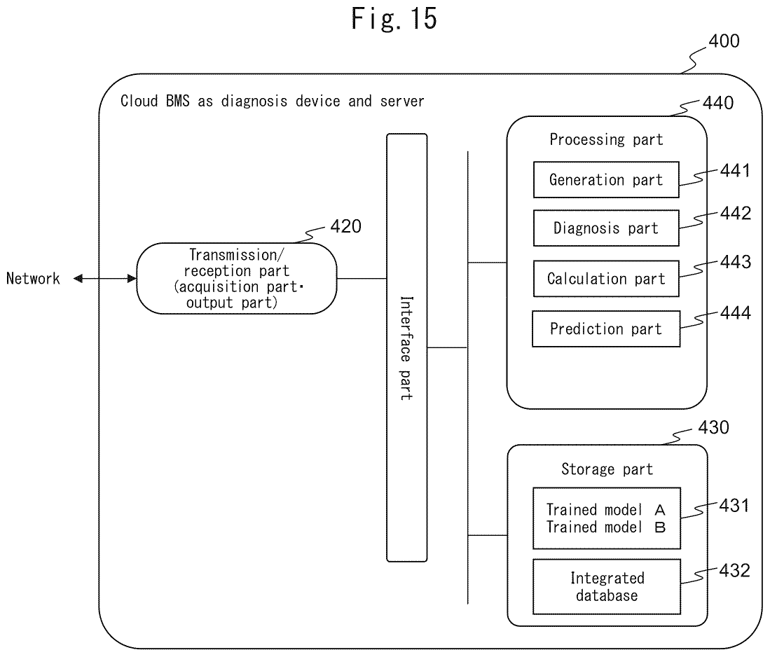

FIG. 15 is a view showing a schematic configuration of a cloud BMS 400 serving as the diagnosis device and server and is combined with the local BMS 300 of FIG. 4. The cloud BMS 400 comprises an acquisition part (the reception part of the transmission/reception part 420), an output part (the transmission part of the transmission/reception part 420), a storage part 430, and a processing part 440. The storage part 430 stores a trained model 431 including the trained model A and/or B, and an integrated database 432. The processing part 440 includes a generation part 441, a diagnosis part 442, a calculation part 443, and a prediction part 444. The transmission/reception part, storage part, and processing part are connected to each other via buses, an interface part, or the like.

In this aspect, the cloud BMS 400 of FIG. 15 performs only the diagnosis processing, the calculation and prediction processing of the current and future lithium deposition risk X using the diagnosis part, calculation part, and prediction part, and transmits the results of the diagnosis processing and the calculation and prediction processing to the local BMS 300. The local BMS 300 of FIG. 4 can then perform labeling processing and control processing using the calculation part and control part. Alternatively, the cloud BMS 400 of FIG. 15 performs only the diagnosis processing, the calculation and prediction processing of the current and future lithium deposition risk X, and the labeling processing using the diagnosis part, calculation part, and prediction part, and transmits the results of the diagnosis processing and the calculation and prediction processing to the local BMS 300. The local BMS 300 of FIG. 4 can then perform control processing using the calculation part and control part.

### Modification Example 2

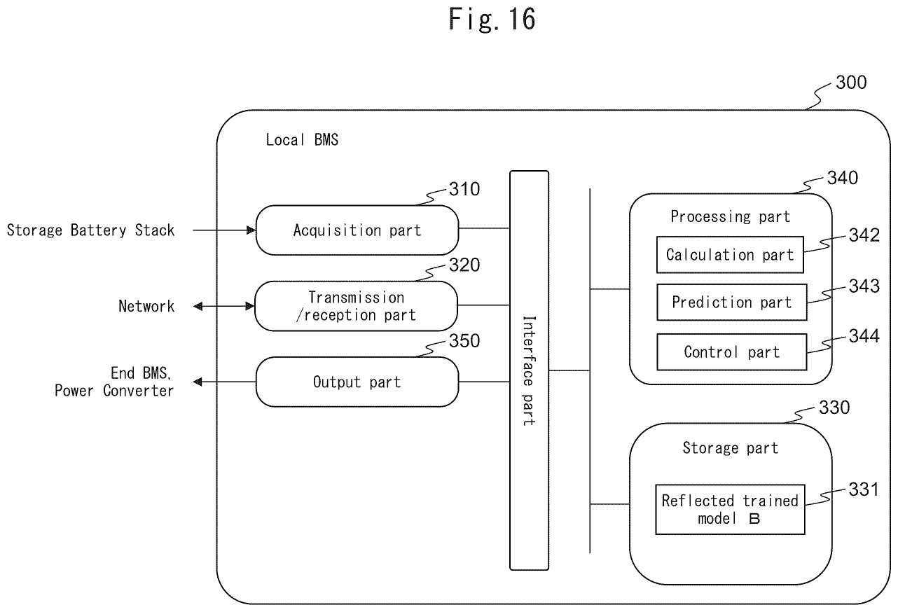

FIG. 16 is a view showing a schematic configuration of the local BMS 300. The local BMS 300 comprises an acquisition part 310, a transmission part (transmission/reception part 320), a reception part (transmission/reception part 320), a storage part 330, a processing part 340, and an output part 350. The reception part receives a trained model 331 including the trained model B transmitted from the cloud BMS 400 and stores it in the storage part 330. If there is an existing trained model stored in the storage part 330, the received trained model is reflected in the existing trained model. The storage part 330 stores the trained model 331 including the received (reflected) trained model B, etc. The processing part 340 comprises a calculation part 342, a prediction part 343, and a control part 344. The acquisition part, transmission/reception part, storage part, processing part, and output part are connected to each other via buses, an interface part, or the like.

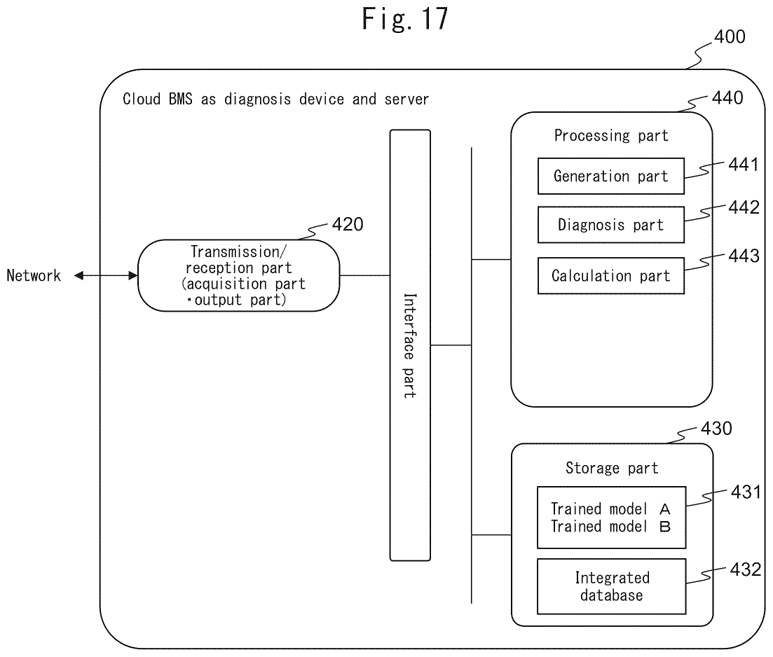

FIG. 17 is a view showing a schematic configuration of a cloud BMS 400 serving as the diagnosis device and server and is combined with the local BMS 300 of FIG. 16. The cloud BMS 400 comprises an acquisition part (the reception part of the transmission/reception part 420), an output part (the transmission part of the transmission/reception part 420), a storage part 430, and a processing part 440. The storage part 430 stores a trained model 431 including the trained models A and B, and an integrated database 432. The processing part 440 includes a generation part 441, a diagnosis part 442, and a calculation part 443. The transmission/reception part, storage part, and processing part are connected to each other via a bus, an interface, and the like.

In this aspect, the cloud BMS 400 of FIG. 17 generates the trained model 431 including the trained models A and B, and transmits and reflects the trained model B among them to the local BMS 300 of FIG. 16. The cloud BMS 400 of FIG. 17 performs only the diagnosis processing using the diagnosis part and calculation part, and transmits the results of the diagnosis processing to the local BMS 300. The local BMS 300 of FIG. 16 can then perform calculation and prediction processing of the current and future lithium deposition risk X, labeling processing, and control processing using the calculation part, prediction part, and control part. Alternatively, the cloud BMS 400 of FIG. 17 performs only the diagnosis processing and calculation processing of the current lithium deposition risk X using the diagnosis part and calculation part, and transmits the results of the diagnosis processing and calculation processing to the local BMS 300. The local BMS 300 of FIG. 16 can perform the prediction processing, labeling processing, and control processing of the future lithium deposition risk X using the calculation part, prediction part, and control part.

### Modification Example 3

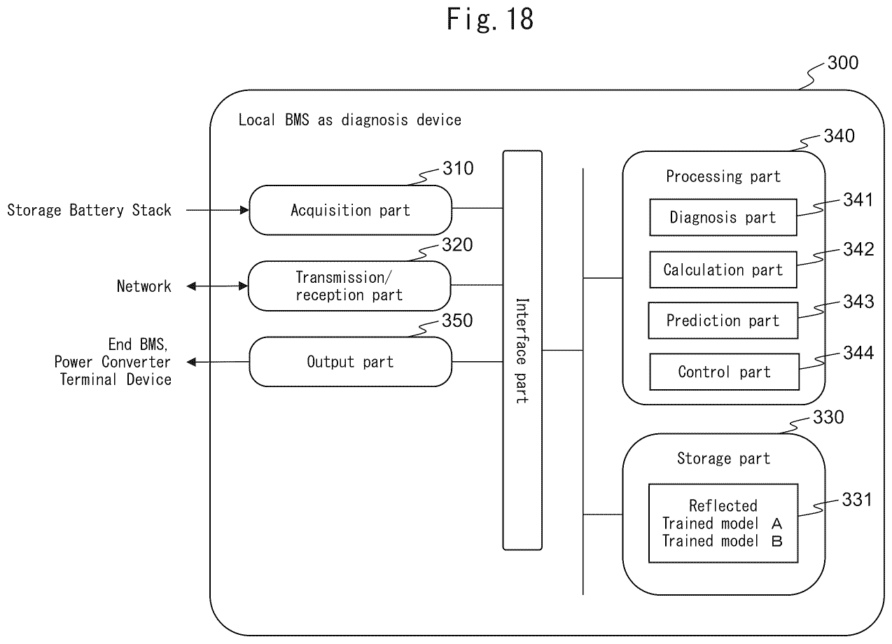

FIG. 18 is a view showing a schematic configuration of a local BMS 300 serving as the diagnosis device. The local BMS 300 comprises an acquisition part 310, a transmission part (transmission/reception part 320), a reception part (transmission/reception part 320), a storage part 330, a processing part 340, and an output part 350. The reception part receives a trained model 331 including the trained model A and/or B transmitted from the cloud BMS 400 and stores it in the storage part 330. If there is an existing trained model stored in the storage part 330, the received trained model is reflected in the existing trained model. The storage part 330 stores the trained model 331 including the received (reflected) trained model A and/or B. The processing part 340 comprises a diagnosis part 341, a calculation part 342, a prediction part 343, and a control part 344. The acquisition part, transmission/reception part, storage part, processing part, and output part are connected to each other via buses, an interface part, or the like.

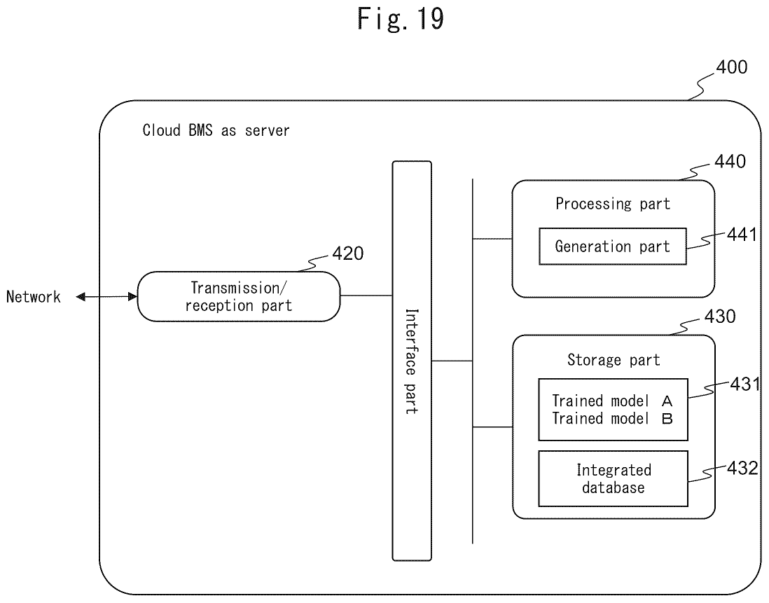

FIG. 19 is a view showing a schematic configuration of a cloud BMS 400 serving as a server which can be combined with the local BMS 300 of FIG. 18. The cloud BMS 400 comprises an acquisition part (the reception part of the transmission/reception part 420), an output part (the transmission part of the transmission/reception part 420), a storage part 430, and a processing part 440. The storage part 430 stores a trained model 431 including the trained model A and/or B, and an integrated database 432. The processing part 440 comprises a generation part 441. The transmission/reception part, storage part, and processing part are connected to each other via buses, an interface part, or the like.

In this aspect, the cloud BMS 400 of FIG. 19 generates a trained model 431 including the trained model A and/or B, and transmits and reflects this to the local BMS 300 in FIG. 18. The local BMS 300 of FIG. 18 can then perform all of the diagnosis processing, calculation and prediction processing of the current and future lithium deposition risk X, labeling processing, and control processing, using the transmitted and reflected trained model A and/or B. In this aspect, the local BMS 300 as the diagnosis device can diagnose and control the storage battery independently of the network N, which has the advantage of enabling stable ESS operation even in poor network environments.

Regarding the details of each functional part and the processing of modification examples 1 to 3, refer to the descriptions of each functional part and the processing described regarding FIGS. 4 and 5.

DESCRIPTION OF REFERENCE SIGNS

1 diagnosis system, 10 energy storage system, 100 PCS, 200 storage battery stack, 210 storage
battery module, 220 sensor part, 230 end BMS, 231 acquisition part, 232 monitoring part, 233
balance adjustment/suspension part, 240 EMS, 300 local BMS, 310 acquisition part, 320
transmission/reception part, 330 storage part, 331 received (reflected) trained model, 340
processing part, 341 diagnosis part, 342 calculation part, 343 prediction part, 344 control part, 350
output part, 400 cloud BMS, 420 transmission/reception part, 430 storage part, 431 trained model,
432 integrated database, 440 processing part, 441 generation part, 442 diagnosis part, 443
calculation part, 444 prediction part, 445 control part, 450 output part, 500 terminal device

1. A diagnosis device for a storage battery used in an energy storage system, the diagnosis device comprising:
a storage part for storing a trained model A which is trained so as to output material deterioration information of a storage battery when charge/discharge data is input,
an acquisition part for acquiring charge/discharge data of the storage battery,
a diagnosis part for diagnosing material deterioration information of the storage battery obtained by inputting charge/discharge data of the storage battery into the trained model A, and
an output part for outputting the material deterioration information obtained from the diagnosis part as diagnosis results.

2. The diagnosis device according to claim 1, wherein material information of the storage battery is material information of at least one selected from the group consisting of a positive electrode, a negative electrode, a separator, and an electrolyte of the storage battery;
optionally wherein the diagnosis device further comprises a calculation part for calculating a lithium deposition risk X of the storage battery based on information including the material deterioration information, wherein the diagnosis results include the lithium deposition risk X;
optionally wherein the calculation part calculates a lithium deposition risk X of the storage battery based on the material deterioration information and information including at least one selected from the group consisting of the charge/discharge data, material information of the storage battery, and an operation condition of the energy storage system;
optionally wherein the calculation part calculates a lithium deposition risk X of the storage battery by calculating a sum of a value obtained by multiplying a lithium deposition risk X_{chem.} estimated from the material deterioration information by a weighting coefficient α_{chem.}, which depends on material information of a negative electrode of the storage battery, and a value obtained by multiplying a lithium deposition risk X_{elec.} estimated from the charge/discharge data by a weighting coefficient α_{elec.}, which depends on material information of a negative electrode of the storage battery, and optionally, multiplying the sum by at least one selected from the group consisting of a weighting coefficient β, which depends on material information of a positive electrode of the storage battery, and a weighting coefficient γ, which depends on the operation condition.

3-5. (canceled)

6. The diagnosis device according to claim 1, wherein the diagnosis device further comprises a calculation part for calculating a deterioration state of the storage battery based on a state of health (SoH) of the storage battery estimated based on charge/discharge data of the storage battery, and the material deterioration information, and the output part outputs the deterioration state as diagnosis results.

7. The diagnosis device according to claim 6, wherein the calculation part is configured so as to calculate a lithium deposition risk X of the storage battery based on information including the material deterioration information, and label a deterioration state of the storage battery based on one or a plurality of predetermined thresholds for each of the SoH and the lithium deposition risk X, and the diagnosis results include results of the labeling.

8. The diagnosis device according to claim 7, wherein the output part transmits the diagnosis results to a terminal device of a user.

9. The diagnosis device according to claim 7, wherein the calculation part calculates an SoH and a lithium deposition risk Xt₁ at a current time point (t₁) based on the material deterioration information, charge/discharge data at a current time point (t₁), and optionally, information including at least one selected from the group consisting of material information of the storage battery and an operation condition of the energy storage system,
optionally wherein material information of the storage battery is material information of at least one selected from the group consisting of a positive electrode, a negative electrode, a separator, and an electrolyte of the storage battery,
optionally wherein the calculation part calculates a lithium deposition risk Xt₁ at the current time point (t₁) by calculating a sum of a value obtained by multiplying a lithium deposition risk X_{chem.} estimated from the material deterioration information by a weighting coefficient α_{chem.}, which depends on material information of a negative electrode of the storage battery, and a value obtained by multiplying a lithium deposition risk X_{elec.} estimated from the charge/discharge data by a weighting coefficient α_{elec.}, which depends on material information of a negative electrode of the storage battery, and optionally, multiplying the sum by at least one selected from the group consisting of a weighting coefficient β, which depends on material information of a positive electrode of the storage battery, and a weighting coefficient γ, which depends on the operation condition; and
optionally wherein the storage part further stores a trained model B which is trained so as to output a future lithium deposition risk X trend when information including an SoH and a lithium deposition risk Xt₁ at the current time point (t₁), past charge/discharge data, and a past SoH trend are input, the diagnosis device further comprises a prediction part, and the prediction part inputs an SoH and a lithium deposition risk Xt₁ at the current time point (t₁) and information including past charge/discharge data and a past SoH trend into the trained model B to predict a future lithium deposition risk X trend, and
the calculation part calculates a lithium deposition risk Xt₂ at a certain future time point (t₂) based on the predicted future lithium deposition risk X trend, and labels a deterioration state of the storage battery based on one or a plurality of predetermined thresholds for the lithium deposition risk Xt₂.

10-12. (canceled)

13. The diagnosis device according to claim 7, further comprising a control part for controlling the storage battery based on results of the labeling.

14. The diagnosis device according to claim 13, wherein the control part controls the storage battery based on results of the labeling and a cause of storage battery deterioration; or the control part controls the storage battery based on results of the labeling and a target operation period of the energy storage system.

15. (canceled)

16. The diagnosis device according to claim 13, wherein the storage battery is composed of a plurality of storage battery modules arranged in series and/or parallel, each of which includes a plurality of cells arranged in series and/or parallel, the diagnosis part and a calculation part diagnose and label a deterioration state of each storage battery module, and the control part controls charge/discharge conditions for each storage battery module.

17. The diagnosis device according to claim 6, wherein material deterioration information of the storage battery is at least one selected from the group consisting of an area, a shape of a deposition region, a deposition weight, a distribution state, and a color tone of deposited lithium metal analyzed from an image of a negative electrode surface of the storage battery, a shape of lithium metal observed by cross-sectional SEM observation of a negative electrode, a chemical shift value (eV) and/or area thereof obtained from an Li(s1) spectrum obtained by XPS analysis, a chemical shift value (ppm) and/or area thereof obtained from a ⁷Li-NMR spectrum, and a g-value or a chemical state expressed as a line width obtained from an ESR spectrum;
optionally wherein the charge/discharge data to be input to the trained model A is at least one selected from the group consisting of a voltage change over time (dOCV/dt-t plot) when the storage battery is charged to an arbitrary SoC and then immediately rested, a voltage change over time (V-t plot) during pulse charging and/or discharging at a constant current, a current change over time (I-t plot) observed during constant voltage charging, charge capacity and discharge capacity at a constant current or constant power, measurement data obtained by an AC impedance method, and mathematically processed data thereof;
optionally wherein estimation of the SoH is performed by estimation based on capacity when the storage battery is charged and discharged at a constant current and a constant voltage, estimation based on internal resistance obtained by an AC impedance method, estimation based on internal resistance obtained from a slope of current-voltage characteristics (IV characteristics), estimation based on internal resistance obtained from voltage transient response when current is changed in steps, estimation by fitting charging curve data using a regression equation or a model, estimation based on an equivalent circuit or physical model which behaves in the same manner as the charge/discharge data of the storage battery, or a combination thereof; and
optionally wherein estimation of the SoH is performed by estimation based on internal resistance obtained from a slope of current-voltage characteristics (IV characteristics).

18-25. (canceled)

26. A diagnosis system for a storage battery used in an energy storage system, the diagnosis system comprising:
a storage device for storing a trained model A which is trained so as to output material deterioration information of a storage battery when charge/discharge data is input,
an acquisition device for acquiring charge/discharge data of the storage battery,
a diagnosis device for diagnosing material deterioration information of the storage battery obtained by inputting charge/discharge data of the storage battery into the trained model A, and
an output device for outputting the material deterioration information obtained from the diagnosis device as diagnosis results.

27. The diagnosis device according to claim 26, wherein the diagnosis system further comprises a calculation device for estimating a state of health (SoH) of the storage battery based on charge/discharge data of the storage battery, and calculating a deterioration state of the storage battery based on the SoH and the material deterioration information, and
the output device outputs the deterioration state as diagnosis results.

28. The diagnosis system according to claim 27, wherein the calculation part is configured so as to calculate a lithium deposition risk X of the storage battery based on information including the material deterioration information, and label a deterioration state of the storage battery based on one or a plurality of predetermined thresholds for each of the SoH and the lithium deposition risk X, and the diagnosis results include results of the labeling.

29. The diagnosis system according to claim 28, wherein the diagnosis system further comprises a display device, and the output device transmits the diagnosis results to the display device and the display device displays the diagnosis results.

30. The diagnosis system according to claim 28, further comprising a controller for controlling the storage battery based on results of the labeling.

31-35. (canceled)

36. A diagnosis method for a storage battery used in an energy storage system, the method comprising the steps of:
acquiring charge/discharge data of the storage battery,
acquiring material deterioration information of the storage battery by inputting charge/discharge data of the storage battery into a trained model A which is trained so as to output material deterioration information of a storage battery when charge/discharge data is input, diagnosing the obtained material deterioration information of the storage battery, and outputting the material deterioration information as diagnosis results.

37. The diagnosis method according to claim 36, the method further comprising the steps of estimating a state of health (SoH) of the storage battery based on charge/discharge data of the storage battery,
calculating a deterioration state of the storage battery based on the SoH and the material deterioration information, and
outputting the deterioration state as diagnosis results.

38. The diagnosis method according to claim 37, wherein calculation of the deterioration state includes calculating a lithium deposition risk X of the storage battery based on information including the material deterioration information, and labeling a deterioration state of the storage battery based on one or a plurality of predetermined thresholds for each of the SoH and the lithium deposition risk X, and the diagnosis results include results of the labeling.

39. The diagnosis method according to claim 38, further comprising the step of displaying the output diagnosis results on a display part.

40. The diagnosis method according to claim 38, wherein the diagnosis method further comprises the step of controlling the storage battery based on results of the labeling.

41-45. (canceled)
